(19) United States
(12) Patent Application Publication
(10) Pub. No.: US 2025/0180993 A1
(43) Pub. Date: Jun. 5, 2025

(54) RESIST UNDERLAYER FILM-FORMING COMPOSITION FOR REDUCING ENVIRONMENTAL LOAD

(71) Applicant: NISSAN CHEMICAL CORPORATION, Tokyo (JP)

(72) Inventors: Satoshi KAMIBAYASHI, Toyama-shi (JP); Takahiro KISHIOKA, Toyama-shi (JP)

(73) Assignee: NISSAN CHEMICAL CORPORATION, Tokyo (JP)

(21) Appl. No.: 18/862,074

(22) PCT Filed: Jun. 9, 2023
(86) PCT No.: PCT/JP2023/021446

§ 371 Date: Oct. 31, 2024

(30) Foreign Application Priority Data
Jun. 10, 2022 (JP) 2022-094144

(51) Int. Cl. G03F 7/11

(52) U.S. Cl. CPC G03F 7/11

(57) ABSTRACT

A resist underlayer film-forming composition containing: a first component; a second component; and a solvent, in which the second component is a water-soluble polymer, a mass ratio (first component:second component) between the first component and the second component is 99:1 to 50:50, and the solvent contains water in an amount of 50 mass % or more relative to the solvent.

### TECHNICAL FIELD

The present invention relates to a resist underlayer film-forming composition, a resist underlayer film, a semiconductor processing substrate, a method for producing a semiconductor element, and a method for forming a pattern.

### BACKGROUND ART

In the related art, fine processing by lithography using a photoresist composition has been performed in the production of semiconductor devices. The fine processing is a processing method of forming a thin film of a photoresist composition on a silicon wafer, irradiating the thin film with active energy rays such as ultraviolet rays through a mask pattern having a semiconductor device pattern drawn thereon, developing the irradiated thin film, and etching the silicon wafer using the resultant resist pattern serving as a protective film.

However, in recent years, as a result of an increase in the degree of integration of semiconductor devices, active energy rays having a shorter wavelength have tended to be used, i.e. shifting from KrF excimer laser (248 nm) to ArF excimer laser (193 nm). The use of such active energy rays having a shorter wavelength has caused a serious problem in terms of irregular reflection and standing wave of active energy rays from a substrate. Thus, there has been widely studied a method of providing a bottom anti-reflective coating (BARC), i.e. a resist underlayer film between a photoresist and a substrate.

For example, the present applicant has proposed an anti-reflective coating-forming composition which has a high reflected-light preventing effect, does not cause intermixing with a resist layer, can provide an excellent resist pattern and a wide focus depth margin, and can produce an anti-reflective coating for lithography having a higher dry etching rate than a resist (see Patent Literature 1).

### CITATION LIST

### Patent Literature

Patent Literature 1: WO 2003/017002 A

### SUMMARY OF INVENTION

### Technical Problem

The resist underlayer film-forming composition is generally an organic solvent-based composition prepared by dissolution of a polymer in an organic solvent.

Replacement of organic solvent-based paints with aqueous paints has been actively studied from the viewpoints of the influence of volatile organic solvents on the environment, the health of operators who handle paints, and the like.

The resist underlayer film-forming composition is used in a clean room. Accordingly, volatile organic solvents are hardly released into the environment, and operators are not exposed to the organic solvents.

However, an aqueous composition is preferred from the viewpoint of treatment of waste liquid and the viewpoint that the organic solvent-based composition is combustible and care is required for handling and transportation.

It is an object of the present invention to provide a resist underlayer film-forming composition using water as a solvent, a resist underlayer film, a semiconductor processing substrate, a method for producing a semiconductor element, and a method for forming a pattern.

### Solution to Problem

As a result of intensive studies to solve the above problem, the present inventors have found that the above problem can be solved, thereby completing the present invention having the following gist.

That is, the present invention includes the followings.

[1] A resist underlayer film-forming composition containing:
a first component,
a second component, and
a solvent,
wherein the second component is a water-soluble polymer,
a mass ratio (first component:second component) between the first component and the second component is 99:1 to 50:50, and
the solvent contains water in an amount of 50 mass % or more relative to the solvent.

[2] A resist underlayer film-forming composition containing:
a first component; and
a solvent,
wherein the first component is a compound containing at least one selected from a structure represented by the following Formula (1) and a structure represented by the following Formula (2), and
the solvent contains water in an amount of 50 mass % or more relative to the solvent:

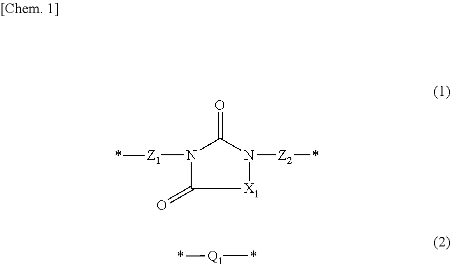

where in Formula (1), X₁ represents a group represented by any one of the following Formulae (1-1) to (1-4), and Z₁ and Z₂ each independently represent a single bond or a divalent group represented by the following Formula (1-5),
in Formula (2), Q₁ represents a divalent organic group having at least one selected from an aromatic hydrocarbon ring and an aliphatic hydrocarbon ring:

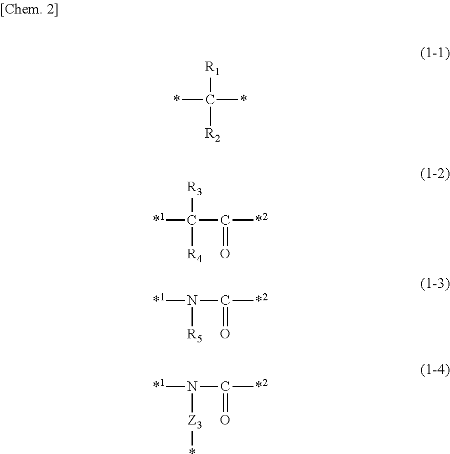

where in Formulae (1-1) to (1-3), R₁ to R₅ each independently represent a hydrogen atom, an alkyl group having 1 to 10 carbon atoms and optionally interrupted by an oxygen atom or a sulfur atom, an alkenyl group having 2 to 10 carbon atoms and optionally interrupted by an oxygen atom or a sulfur atom, an alkynyl group having 2 to 10 carbon atoms and optionally interrupted by an oxygen atom or a sulfur atom, a benzyl group, or a phenyl group, and the phenyl group is optionally substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R₁ and R₂ may be bonded together to form a ring having 3 to 6 carbon atoms, and R₃ and R₄ may be bonded together to form a ring having 3 to 6 carbon atoms,
in Formula (1-4), Z₃ represents a single bond or a divalent group represented by the following Formula (1-5), and
each asterisk * represents a bonding hand, *1 represents a bonding hand bonded to a carbon atom in Formula (1), and *2 represents a bonding hand bonded to a nitrogen atom in Formula (1):

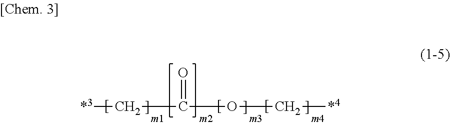

where in Formula (1-5), m1 is an integer of 0 to 4, m2 is 0 or 1, m3 is 0 or 1, and m4 is an integer of 0 to 2, provided that when m3 is 1, m1 and m2 do not simultaneously become 0, *3 represents a bonding hand bonded to a nitrogen atom in Formula (1) or (1-4), and *4 represents a bonding hand.

[3] The resist underlayer film-forming composition according to [1], wherein the first component is a compound containing at least one selected from a structure represented by the following Formula (1) and a structure represented by the following Formula (2):

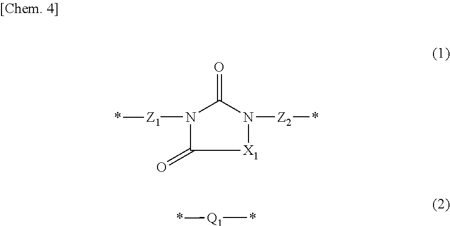

where in Formula (1), X₁ represents a group represented by any one of the following Formulae (1-1) to (1-4), and Z₁ and Z₂ each independently represent a single bond or a divalent group represented by the following Formula (1-5),
in Formula (2), Q₁ represents a divalent organic group having at least one selected from an aromatic hydrocarbon ring and an aliphatic hydrocarbon ring:

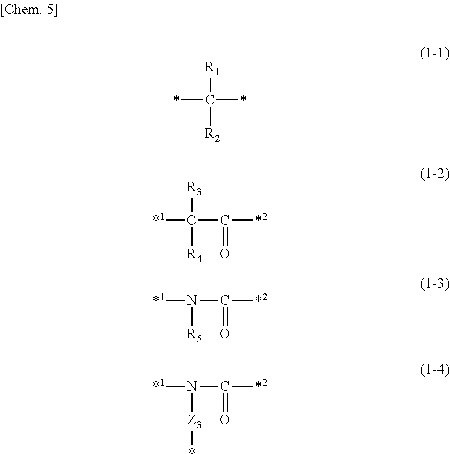

where in Formulae (1-1) to (1-3), R₁ to R₅ each independently represent a hydrogen atom, an alkyl group having 1 to 10 carbon atoms and optionally interrupted by an oxygen atom or a sulfur atom, an alkenyl group having 2 to 10 carbon atoms and optionally interrupted by an oxygen atom or a sulfur atom, an alkynyl group having 2 to 10 carbon atoms and optionally interrupted by an oxygen atom or a sulfur atom, a benzyl group, or a phenyl group, and the phenyl group is optionally substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R₁ and R₂ may be bonded together to form a ring having 3 to 6 carbon atoms, and R₃ and R₄ may be bonded together to form a ring having 3 to 6 carbon atoms,
in Formula (1-4), Z₃ represents a single bond or a divalent group represented by the following Formula (1-5), and
each asterisk * represents a bonding hand, *1 represents a bonding hand bonded to a carbon atom in Formula (1), and *2 represents a bonding hand bonded to a nitrogen atom in Formula (1):

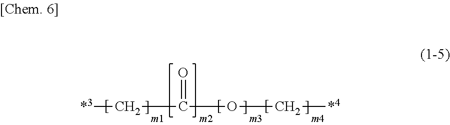

where in Formula (1-5), m1 is an integer of 0 to 4, m2 is 0 or 1, m3 is 0 or 1, and m4 is an integer of 0 to 2, provided that when m3 is 1, m1 and m2 do not simultaneously become 0, *3 represents a bonding hand bonded to a nitrogen atom in Formula (1) or (1-4), and *4 represents a bonding hand.

[4] The resist underlayer film-forming composition according to [2] or [3], wherein Q₁ is represented by the following Formula (2-1):

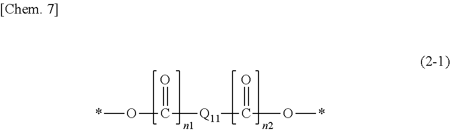

where in Formula (2-1), Q₁₁ represents a divalent organic group represented by any one of the following Formulae (2-1-1) to (2-1-4), n1 and n2 each independently represent 0 or 1, and each asterisk * represents a bonding hand:

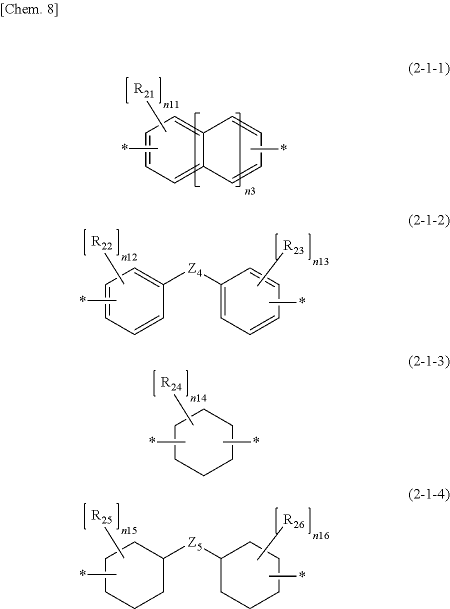

where in Formulae (2-1-1) to (2-1-4), R₂₁ to R₂₆ each independently represent a halogen atom, a hydroxy group, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms, and each asterisk * represents a bonding hand,
in Formula (2-1-1), n3 represents 0 or 1, when n3 is 0, n11 represents an integer of 0 to 4, when n3 is 1, n11 represents an integer of 0 to 6, and when R₂₁ is two or more, the two or more R² is may be identical to or different from each other or one another,
in Formula (2-1-2), Z₄ represents a single bond, an oxygen atom, a sulfur atom, a carbonyl group, a sulfonyl group, or an alkylene group having 1 to 6 carbon atoms, n12 and n13 each independently represent an integer of 0 to 4, when R₂₂ is two or more, the two or more R₂₂s may be identical to or different from each other or one another, and when R₂₃ is two or more, the two or more R₂₃s may be identical to or different from each other or one another,
in Formula (2-1-3), n14 represents an integer of 0 to 4, and when R₂₄ is two or more, the two or more R₂₄s may be identical to or different from each other or one another, and
in Formula (2-1-4), Z₅ represents a single bond, an oxygen atom, a sulfur atom, a carbonyl group, a sulfonyl group, or an alkylene group having 1 to 6 carbon atoms, n15 and n16 each independently represent an integer of 0 to 4, when R₂₅ is two or more, the two or more R₂₅s may be identical to or different from each other or one another, and when R₂₆ is two or more, the two or more R₂₆s may be identical to or different from each other or one another.

[5] The resist underlayer film-forming composition according to any one of [1] to [3], wherein the first component includes at least one of a structure represented by the following Formula (E-1) or a structure represented by the following Formula (E-2):

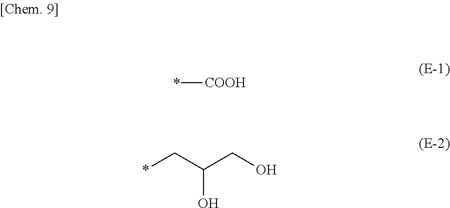

where in Formulae (E-1) and (E-2), each asterisk * represents a bonding hand.

[6] The resist underlayer film-forming composition according to [2], further containing a second component, wherein the second component is a water-soluble polymer.

[7] The resist underlayer film-forming composition according to [1] or [6], wherein the water-soluble polymer is at least one selected from polyvinyl alcohol, polystyrenesulfonic acid, and water-soluble cellulose.

[8] The resist underlayer film-forming composition according to [6] or [7], wherein a mass ratio (first component:second component) between the first component and the second component is 99:1 to 50:50.

[9] The resist underlayer film-forming composition according to any one of [1] to [8], further containing a crosslinking agent.

[10] The resist underlayer film-forming composition according to any one of [1] to [9], further containing a curing catalyst.

[11]A resist underlayer film which is a cured product of the resist underlayer film-forming composition according to any one of [1] to [10].

[12]A semiconductor processing substrate including:
a semiconductor substrate; and the resist underlayer film according to [11].

[13]A method for producing a semiconductor element, the method including the steps of:
forming a resist underlayer film on a semiconductor substrate using the resist underlayer film-forming composition according to any one of [1] to [10]; and
forming a resist film on the resist underlayer film.

[14]A method for forming a pattern including the steps of:
forming a resist underlayer film on a semiconductor substrate using the resist underlayer film-forming composition according to any one of [1] to [10];
forming a resist film on the resist underlayer film;
irradiating the resist film with light or an electron beam, and then developing the resist film to form a resist pattern; and
etching the resist underlayer film using the resist pattern as a mask.

### Advantageous Effects of Invention

According to the present invention, it is possible to provide a resist underlayer film-forming composition using water as a solvent, a resist underlayer film, a semiconductor processing substrate, a method for producing a semiconductor element, and a method for forming a pattern. The amount of the organic solvent used in this field in the related art can be reduced, and this can contribute to reduction in environmental load.

### BRIEF DESCRIPTION OF DRAWINGS

FIG. 1 is an SEM photograph of an example of forming a resist pattern.

### DESCRIPTION OF EMBODIMENTS

### (Resist Underlayer Film-Forming Composition)

An embodiment of the resist underlayer film-forming composition of the present invention contains a first component and water.

An embodiment of the resist underlayer film-forming composition of the present invention contains a first component, a second component, and water.

### <First Component>

The first component is an organic compound.

The first component is, for example, a component that may be used in combination with the second component, in the resist underlayer film-forming composition. The first component is an organic compound that is dissolved in the solvent in order to be used as the resist underlayer film-forming composition.

The molecular weight of the first component is not particularly limited, and the first component may be a low molecular weight compound or a high molecular weight compound.

The first component is preferably a compound containing at least one selected from a structure represented by the following Formula (1) and a structure represented by the following Formula (2).

When the first component is the compound containing at least one selected from the structure represented by the following Formula (1) and the structure represented by the following Formula (2), excellent solvent resistance and excellent antireflection performance are imparted to the resist underlayer film prepared from the resist underlayer film-forming composition:

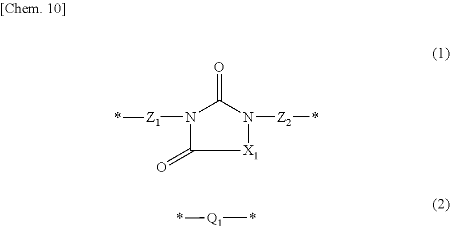

where in Formula (1), X₁ represents a group represented by any one of the following Formulae (1-1) to (1-4), and Z₁ and Z₂ each independently represent a single bond or a divalent group represented by the following Formula (1-5),
in Formula (2), Q₁ represents a divalent organic group having at least one selected from an aromatic hydrocarbon ring and an aliphatic hydrocarbon ring:

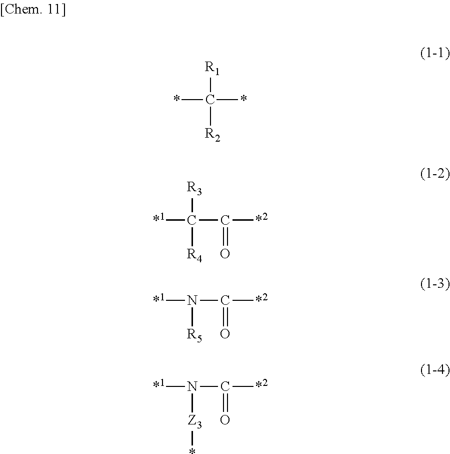

where in Formulae (1-1) to (1-3), R₁ to R₅ each independently represent a hydrogen atom, an alkyl group having 1 to 10 carbon atoms and optionally interrupted by an oxygen atom or a sulfur atom, an alkenyl group having 2 to 10 carbon atoms and optionally interrupted by an oxygen atom or a sulfur atom, an alkynyl group having 2 to 10 carbon atoms and optionally interrupted by an oxygen atom or a sulfur atom, a benzyl group, or a phenyl group, and the phenyl group is optionally substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R₁ and R₂ may be bonded together to form a ring having 3 to 6 carbon atoms, and R₃ and R₄ may be bonded together to form a ring having 3 to 6 carbon atoms,
in Formula (1-4), Z₃ represents a single bond or a divalent group represented by the following Formula (1-5), and
each asterisk * represents a bonding hand, *1 represents a bonding hand bonded to a carbon atom in Formula (1), and *2 represents a bonding hand bonded to a nitrogen atom in Formula (1):

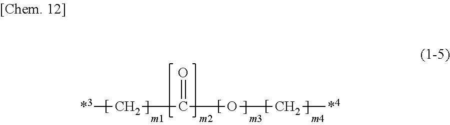

where in Formula (1-5), m1 is an integer of 0 to 4, m2 is 0 or 1, m3 is 0 or 1, and m4 is an integer of 0 to 2, provided that when m3 is 1, m1 and m2 do not simultaneously become 0, *3 represents a bonding hand bonded to a nitrogen atom in Formula (1) or (1-4), and *4 represents a bonding hand.

### <<Formula (1)>>

Examples of the alkyl group having 1 to 10 carbon atoms and optionally interrupted by an oxygen atom or a sulfur atom in R₁ to R₅ in Formulae (1-1) to (1-3) include an alkyl group having 1 to 10 carbon atoms, an alkoxy group having 1 to 10 carbon atoms, an alkoxyalkyl group having 2 to 10 carbon atoms, an alkoxyalkoxyalkyl group having 3 to 10 carbon atoms, an alkylthio group having 1 to 10 carbon atoms, and an alkylthioalkyl group having 2 to 10 carbon atoms.

The alkyl group having 1 to 10 carbon atoms and optionally interrupted by an oxygen atom or a sulfur atom may contain two or more oxygen atoms or sulfur atoms.

X₁ in Formula (1) is preferably represented by Formula (1-3) or Formula (1-4) from the viewpoint of suitably achieving the effects of the present invention.

Examples of Formula (1) include structures exemplified below.

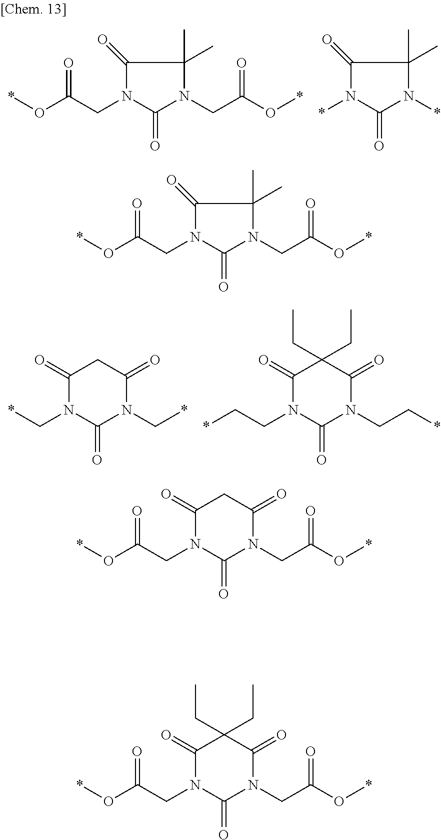

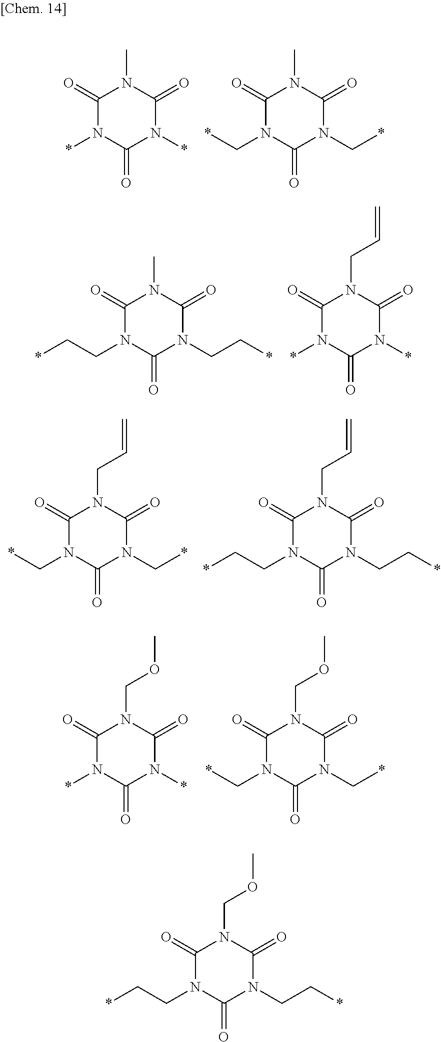

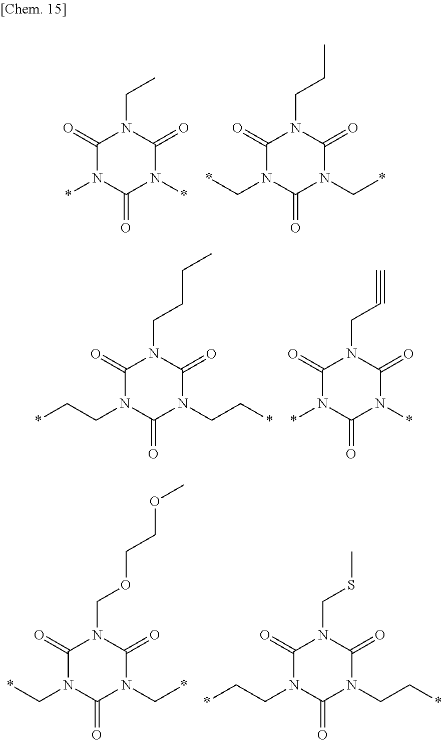

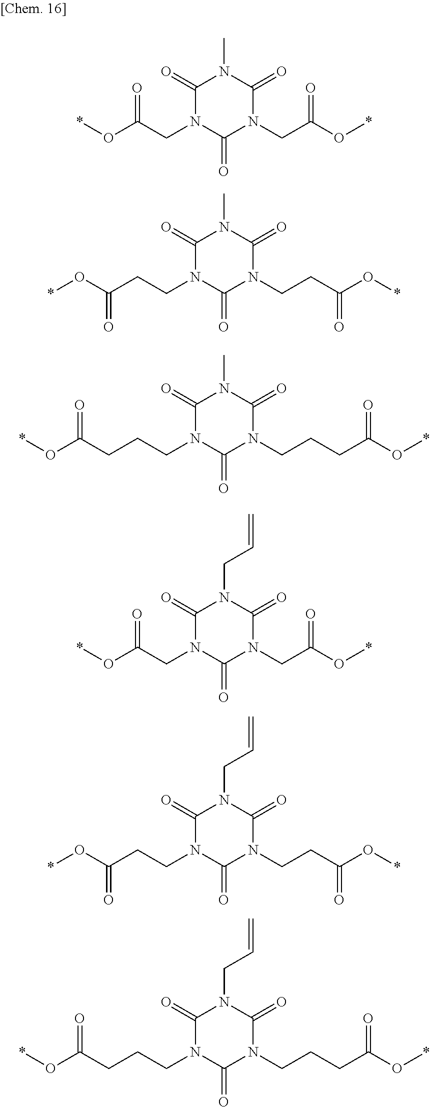

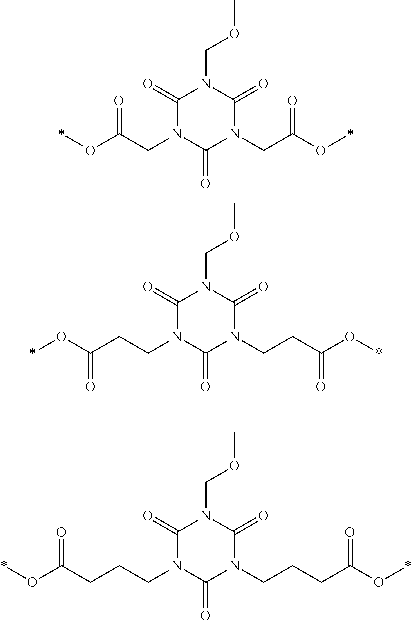

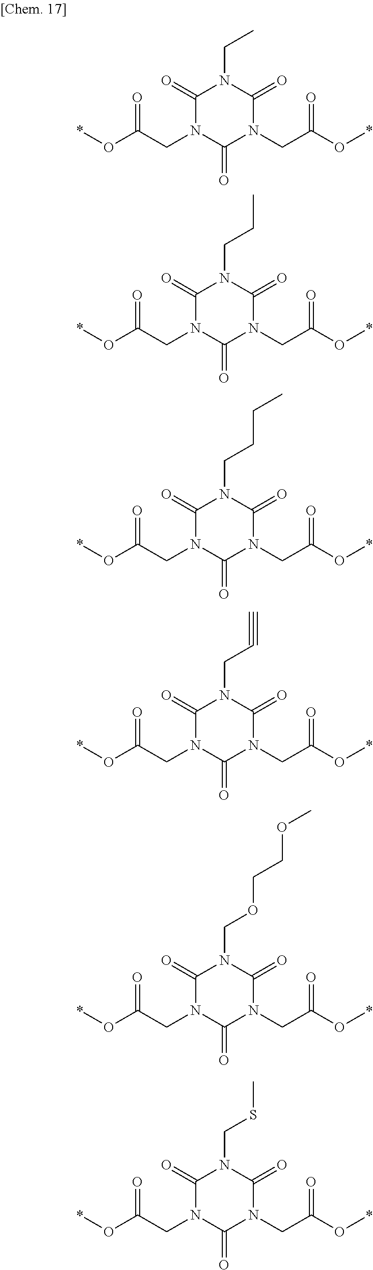

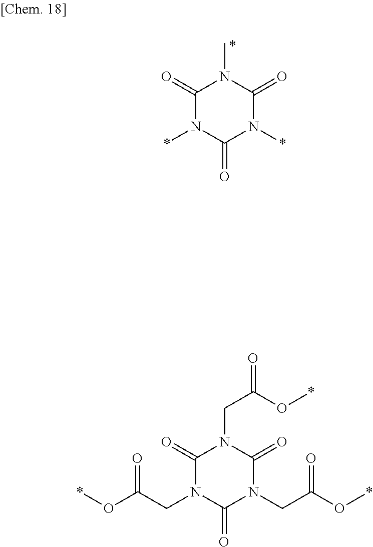 [SMILES: *n1c(=O)n(*)c(=O)n(C)c1=O ; *OC(=O)Cn1c(=O)n(CC(=O)O*)c(=O)n(CC(=O)O*)c1=O]

In the above structures, each asterisk * represents a bonding hand.

### <<Formula (2)>>

Q₁ represents a divalent organic group having at least one selected from an aromatic hydrocarbon ring and an aliphatic hydrocarbon ring.

The aromatic hydrocarbon ring may be a monocyclic ring or a polycyclic ring. The aromatic hydrocarbon ring is not particularly limited, and examples thereof include a benzene ring, a naphthalene ring, and an anthracene ring.

The aliphatic hydrocarbon ring may be a monocyclic ring or a polycyclic ring. The aliphatic hydrocarbon ring is not particularly limited, and examples thereof include a cyclohexane ring.

Q₁ is preferably represented by the following Formula (2-1):

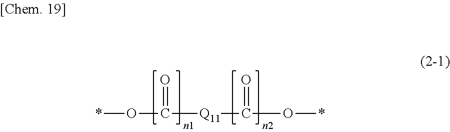

where in Formula (2-1), Q₁ represents a divalent organic group represented by any one of the following Formulae (2-1-1) to (2-1-4), n1 and n2 each independently represent 0 or 1, and each asterisk * represents a bonding hand:

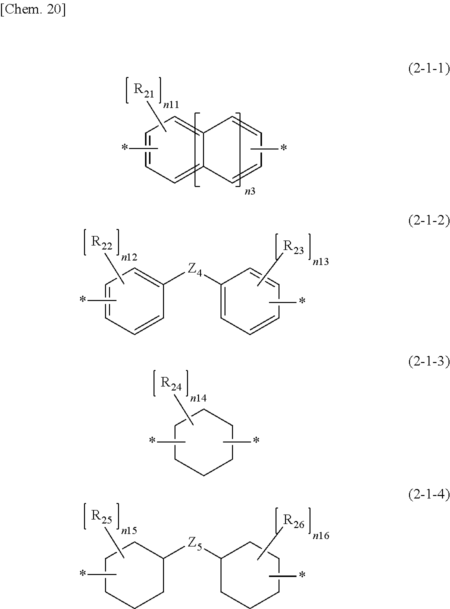

where in Formulae (2-1-1) to (2-1-4), R₂₁ to R₂₆ each independently represent a halogen atom, a hydroxy group, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms, and each asterisk * represents a bonding hand,
in Formula (2-1-1), n3 represents 0 or 1, when n3 is 0, n11 represents an integer of 0 to 4, when n3 is 1, n11 represents an integer of 0 to 6, when R₂₁ is two or more, the two or more R₂₁s may be identical to or different from each other or one another,
in Formula (2-1-2), Z₄ represents a single bond, an oxygen atom, a sulfur atom, a carbonyl group, a sulfonyl group, or an alkylene group having 1 to 6 carbon atoms, n12 and n13 each independently represent an integer of 0 to 4, when R₂₂ is two or more, the two or more R₂₂s may be identical to or different from each other or one another, and when R₂₃ is two or more, the two or more R₂₃s may be identical to or different from each other or one another,
in Formula (2-1-3), n14 represents an integer of 0 to 4, when R₂₄ is two or more, the two or more R₂₄s may be identical to or different from each other or one another, and
in Formula (2-1-4), Z₅ represents a single bond, an oxygen atom, a sulfur atom, a carbonyl group, a sulfonyl group, or an alkylene group having 1 to 6 carbon atoms, n15 and n16 each independently represent an integer of 0 to 4, when R₂₅ is two or more, the two or more R₂₅s may be identical to or different from each other or one another, and when R₂₆ is two or more, the two or more R₂₆s may be identical to or different from each other or one another.

In the present specification, examples of the halogen atom include a fluorine atom, a chlorine atom, a bromine atom, and an iodine atom.

In the present specification, the alkyl group is not limited to be linear, and may be branched or cyclic. Examples of the linear or branched alkyl group include methyl group, ethyl group, isopropyl group, tert-butyl group, and n-hexyl group. Examples of the cyclic alkyl group (cycloalkyl group) include cyclobutyl group, cyclopentyl group, and cyclohexyl group.

In the present specification, examples of the alkoxy group include methoxy group, ethoxy group, n-pentyloxy group, and isopropoxy group.

In the present specification, examples of the alkylthio group include methylthio group, ethylthio group, n-pentylthio group, and isopropylthio group.

In the present specification, examples of the alkenyl group include ethenyl group, 1-propenyl group, 2-propenyl group, 1-methyl-1-ethenyl group, 1-butenyl group, 2-butenyl group, 3-butenyl group, 2-methyl-1-propenyl group, and 2-methyl-2-propenyl group.

In the present specification, the alkynyl group is, for example, a group in which a double bond of each of the alkenyl groups listed in the examples of the “alkenyl group” is replaced with a triple bond.

In the present specification, examples of the alkenyloxy group include vinyloxy group, 1-propenyloxy group, 2-n-propenyloxy group (allyloxy group), 1-n-butenyloxy group, and prenyloxy group.

In the present specification, examples of the alkynyloxy group include 2-propynyloxy group, 1-methyl-2-propynyloxy group, 2-methyl-2-propynyloxy group, 2-butynyloxy group, and 3-butynyloxy group.

In the present specification, examples of the acyl group include acetyl group and propionyl group.

In the present specification, examples of the aryloxy group include phenoxy group and naphthyloxy.

In the present specification, examples of the arylcarbonyl group include phenylcarbonyl group.

In the present specification, examples of the aralkyl group include benzyl group and phenethyl group.

In the present specification, examples of the alkylene group include methylene group, ethylene group, 1,3-propylene group, 2,2-propylene group, 1-methylethylene group, 1,4-butylene group, 1-ethylethylene group, 1-methylpropylene group, 2-methylpropylene group, 1,5-pentylene group, 1-methylbutylene group, 2-methylbutylene group, 1,1-dimethylpropylene group, 1,2-dimethylpropylene group, 1-ethylpropylene group, 2-ethylpropylene group, 1,6-hexylene group, 1,4-cyclohexylene group, 1,8-octylene group, 2-ethyloctylene group, 1,9-nonylene group, and 1,10-decylene group.

Examples of the structure represented by Formula (2-1) include structures exemplified below.

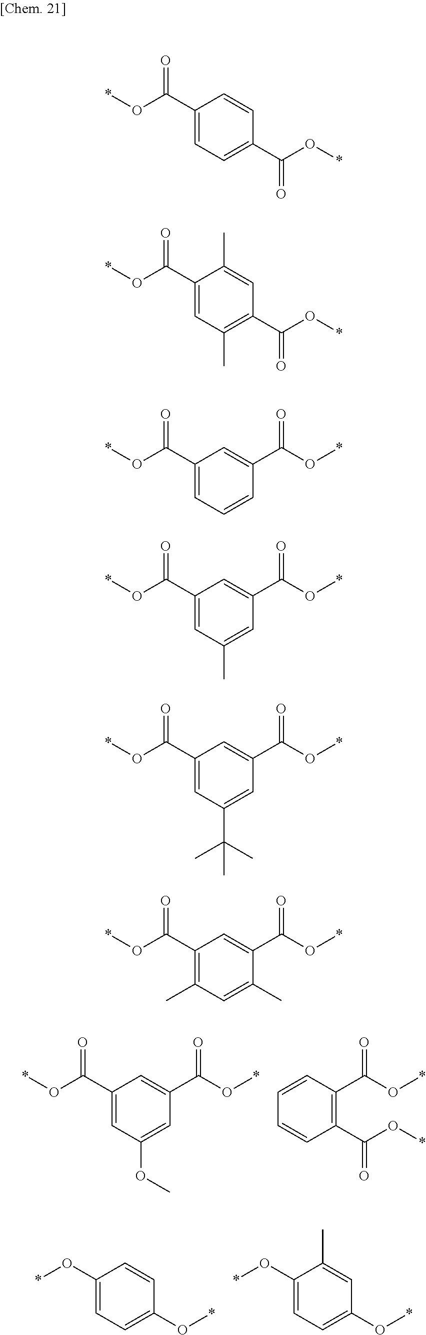

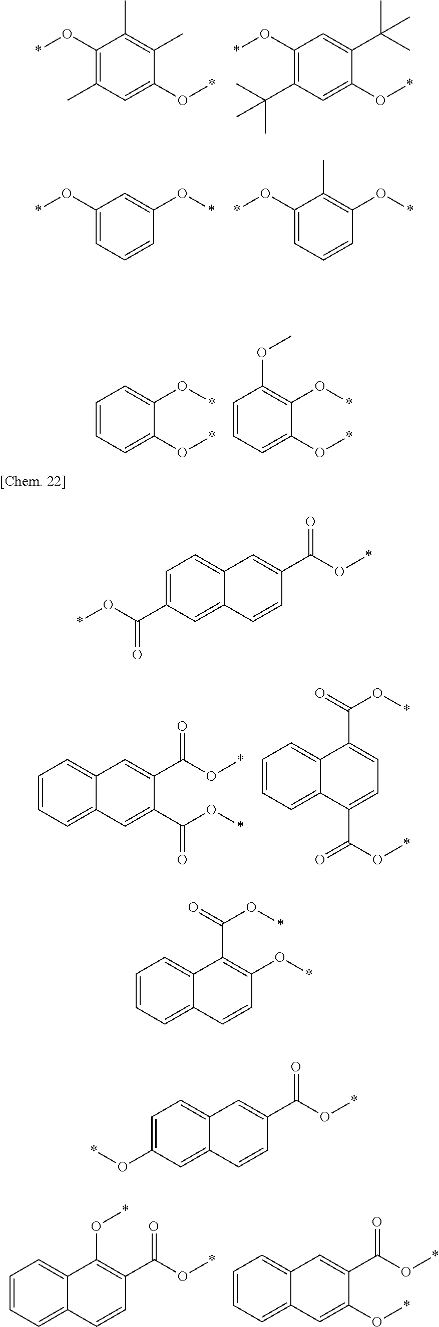

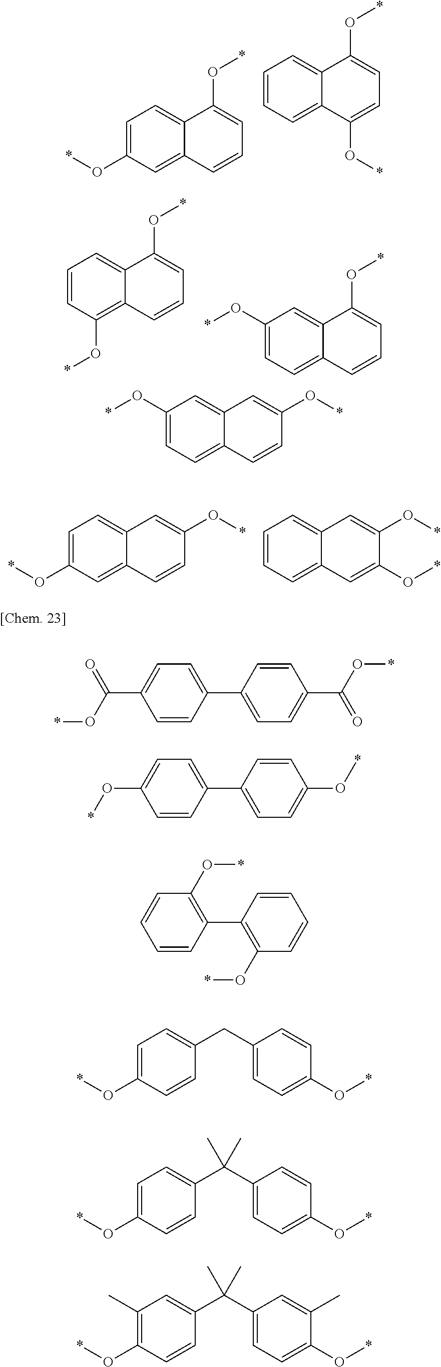

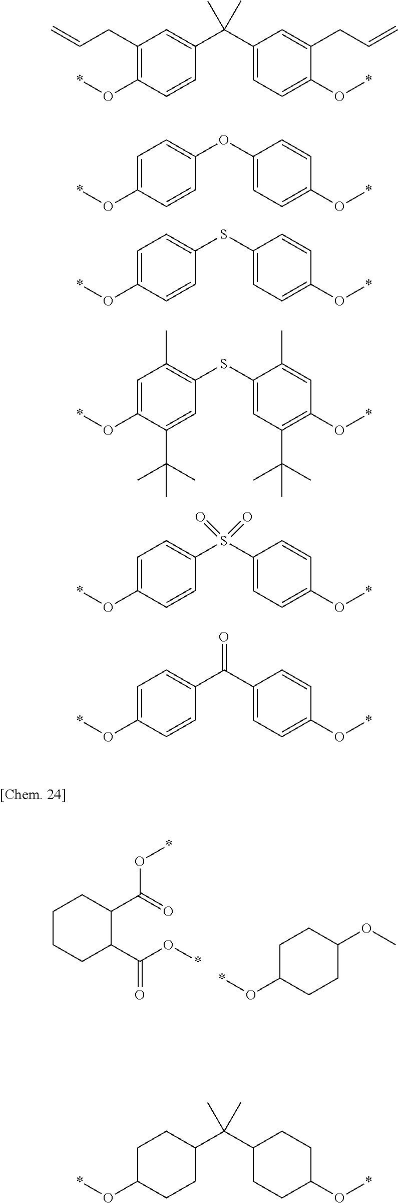

In the above structures, each asterick * represents a bonding hand.

Further, the first component is preferably a compound containing at least one selected from a structure represented by the following Formula (11) and a structure represented by the following Formula (12).

Furthermore, the first component is preferably a compound containing at least one selected from a structure represented by Formula (1), a structure represented by Formula (2), a structure represented by Formula (11), and a structure represented by Formula (12):

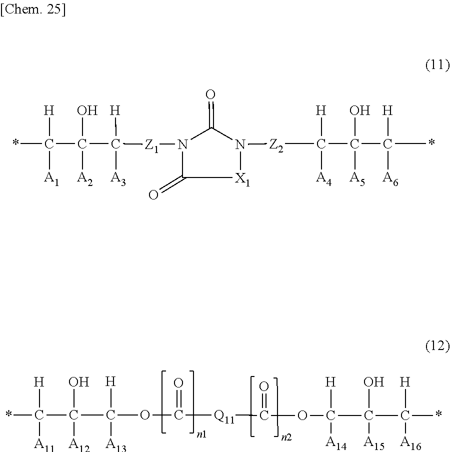

where in Formula (11), X₁ represents a group represented by any one of Formulae (1-1) to (1-3) above and the following Formula (1-4 A), Z₁ and Z₂ each independently represent a single bond or a divalent group represented by Formula (1-5), provided that *3 in Formula (1-5) represents a bonding hand bonded to a nitrogen atom in Formula (11). A₁, A₂, A₃, A₄, A₅ and A₆ each independently represent a hydrogen atom, a methyl group or an ethyl group, and each asterisk * represents a bonding hand, and
in Formula (12), Q₁₁ represents a divalent organic group represented by any one of Formulae (2-1-1) to (2-1-4) above, n1 and n2 each independently represent 0 or 1, and A₁₁, A₁₂, A₁₃, A₁₄, A₁₅ and A₁₆ each independently represent a hydrogen atom, a methyl group or an ethyl group, and each asterisk * represents a bonding hand:

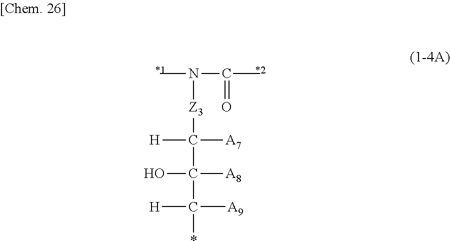

where in Formula (1-4A), Z₃ represents a single bond or a divalent group represented by Formula (1-5), provided that *3 in Formula (1-5) represents a bonding hand bonded to a nitrogen atom in Formula (1-4A). A₇, A₈, and A₉ each independently represent a hydrogen atom, a methyl group, or an ethyl group, each asterisk * represents a bonding hand, *1 represents a bonding hand bonded to a carbon atom in Formula (11), and *2 represents a bonding hand bonded to a nitrogen atom in Formula (11).

The first component preferably includes at least one of a structure represented by the following Formula (E-1) or a structure represented by the following Formula (E-2). When the first component includes these structures, the solubility of the first component in water can be enhanced.

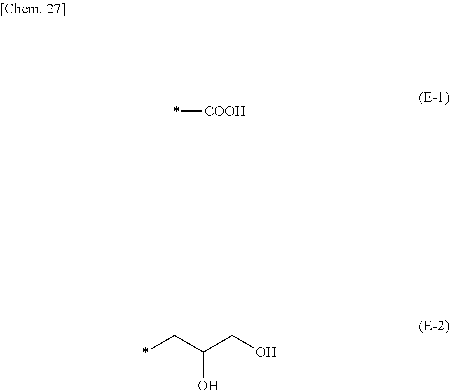

Where in Formulae (E-1) and (E-2), each asterisk * represents a bonding hand.

The number of the structures represented by Formula (E-1) and the number of the structures represented by Formula (E-2) are preferably plural in the first component, and more preferably 2 to 3 in the compound as the first component.

The molecular weight of the first component is not particularly limited.

From the viewpoint of the solubility in water, the weight-average molecular weight of the first component is preferably small.

The weight-average molecular weight of the first component is, for example, 300 to 100,000, preferably 300 to 50,000, more preferably 300 to 10,000, and particularly preferably 300 to 5,000.

A method for producing an example of the first component will be described.

An example of the first component is prepared, for example, by the following reactions (I) to (III).

(I) Reaction between at least one of a compound represented by the following Formula (11A) or a compound represented by the following Formula (12A) and a compound represented by the following Formula (EA):

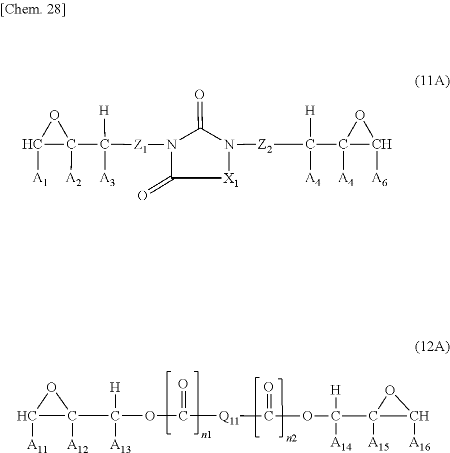

where in Formula (11A), X₁ represents a group represented by any one of Formulae (1-1) to (1-3) above and the following Formula (1-4B), Z₁ and Z₂ each independently represent a single bond or a divalent group represented by Formula (1-5), provided that *3 in Formula (1-5) represents a bonding hand bonded to a nitrogen atom in Formula (11A), and A₁, A₂, A₃, A₄, A₅ and A₆ each independently represent a hydrogen atom, a methyl group or an ethyl group, and
in Formula (12A), Q₁₁ represents a divalent organic group represented by any one of Formulae (2-1-1) to (2-1-4) above, n1 and n2 each independently represent 0 or 1, and A₁₁, A₁₂, A₁₃, A₁₄, A₁₅ and A₁₆ each independently represent a hydrogen atom, a methyl group or an ethyl group:

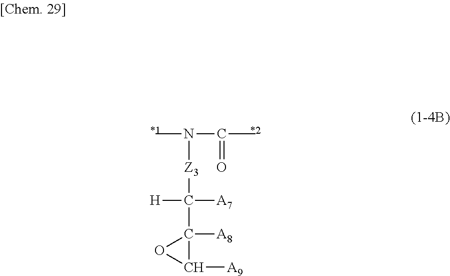

where in Formula (1-4B), Z₃ represents a single bond or a divalent group represented by Formula (1-5) above, provided that *3 in Formula (1-5) represents a bonding hand bonded to a nitrogen atom in Formula (1-4B), A₇, A₈, and A₉ each independently represent a hydrogen atom, a methyl group, or an ethyl group, *1 represents a bonding hand bonded to a carbon atom in Formula (11A), and *2 represents a bonding hand bonded to a nitrogen atom in Formula (11A).

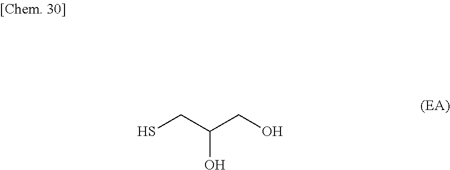

Examples of the compound represented by Formula (11 A) include the following compounds.

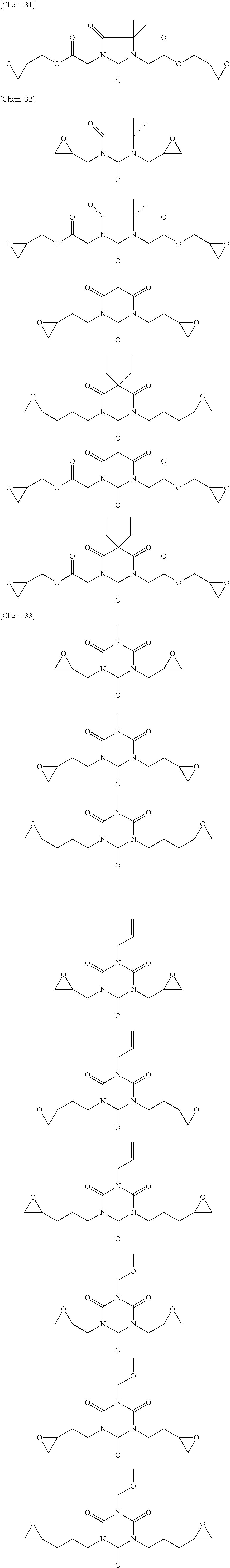

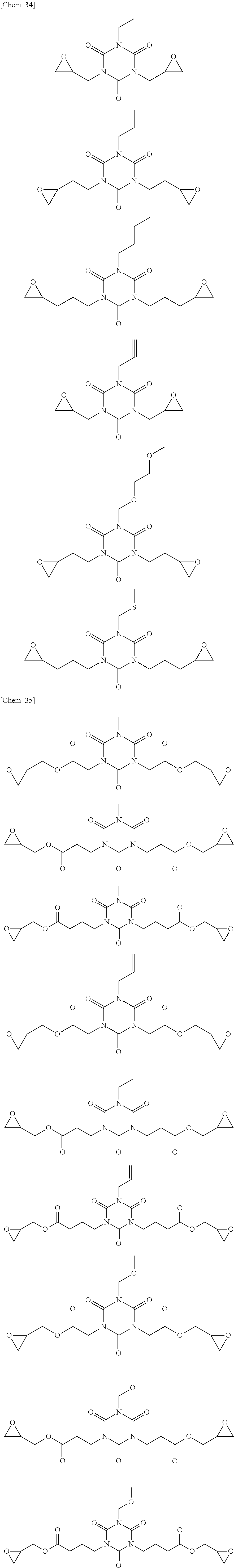

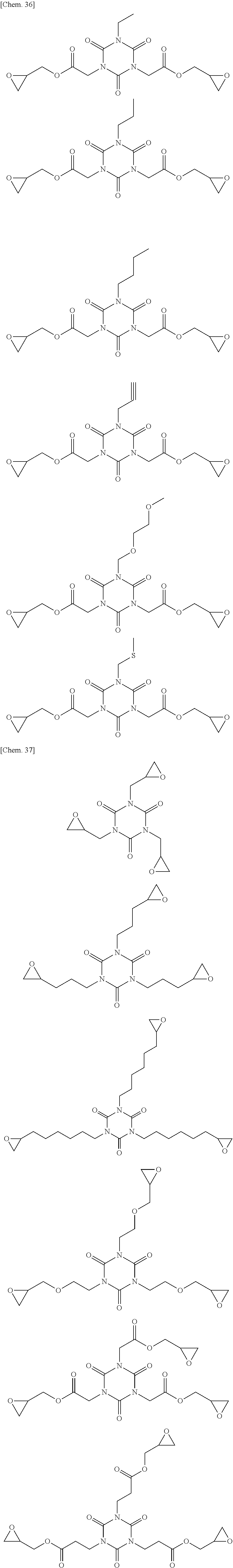

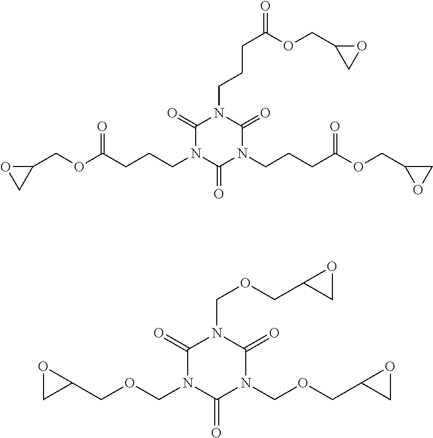 [SMILES: O=C(CCCn1c(=O)n(CCCC(=O)OCC2CO2)c(=O)n(CCCC(=O)OCC2CO2)c1=O)OCC1CO1 ; O=c1n(COCC2CO2)c(=O)n(COCC2CO2)c(=O)n1COCC1CO1]

Examples of the compound represented by Formula (12A) include the following compounds.

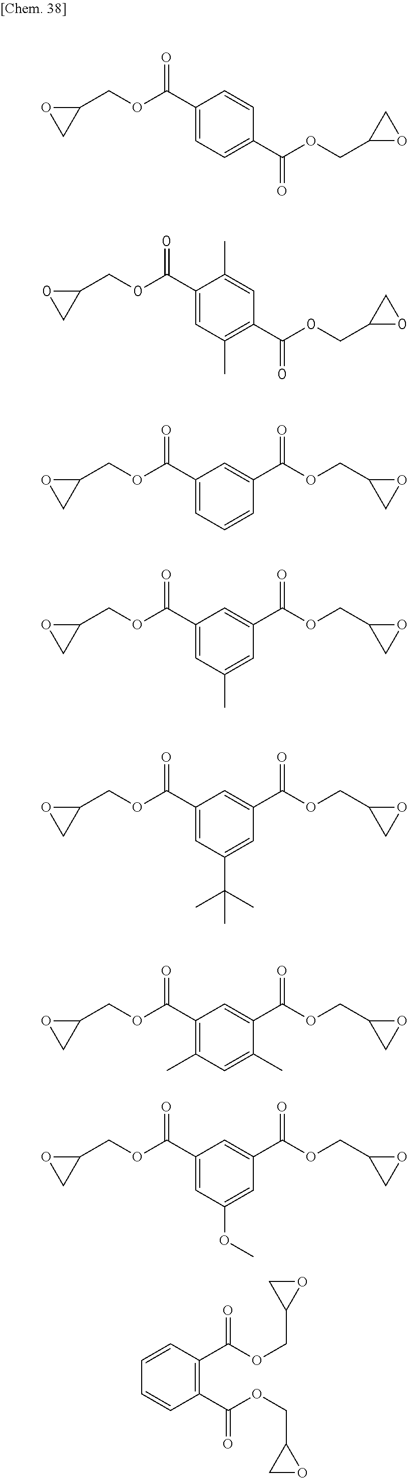

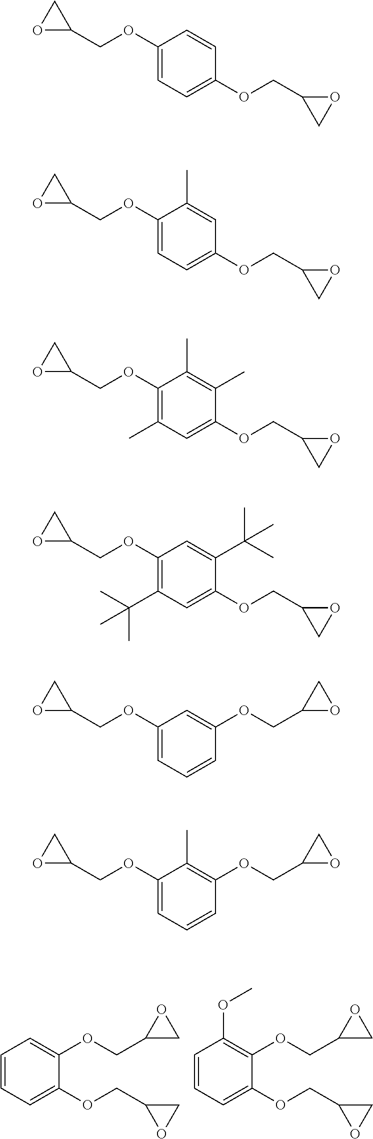

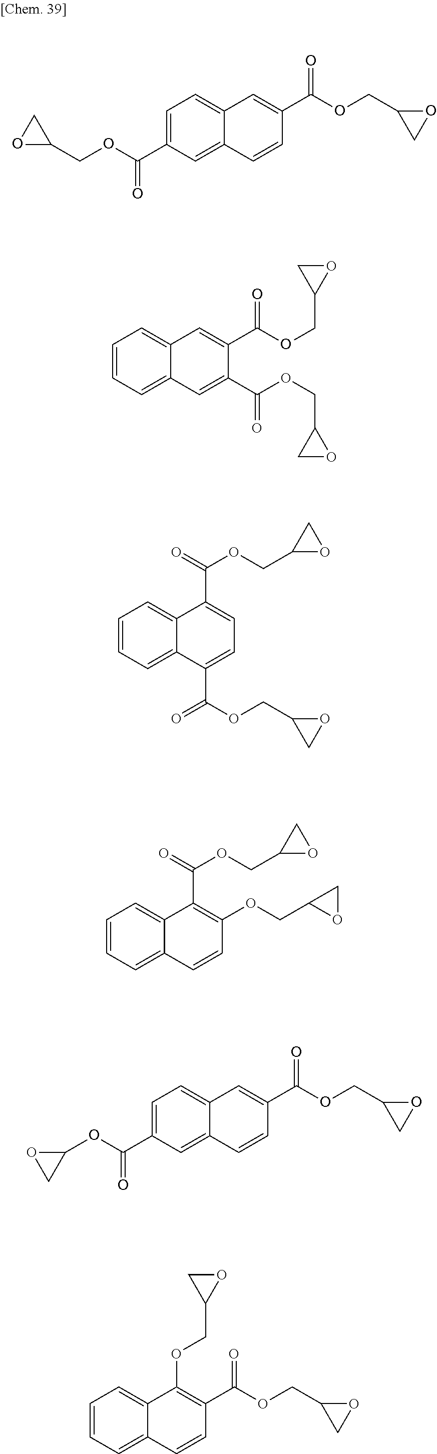 [SMILES: O=C(OCC1CO1)c1ccc2cc(C(=O)OCC3CO3)ccc2c1 ; O=C(OCC1CO1)c1cc2ccccc2cc1C(=O)OCC1CO1 ; O=C(OCC1CO1)c1ccc(C(=O)OCC2CO2)c2ccccc12 ; O=C(OCC1CO1)c1c(OCC2CO2)ccc2ccccc12 ; O=C(OCC1CO1)c1ccc2cc(C(=O)OC3CO3)ccc2c1 ; O=C(OCC1CO1)c1ccc2ccccc2c1OCC1CO1]

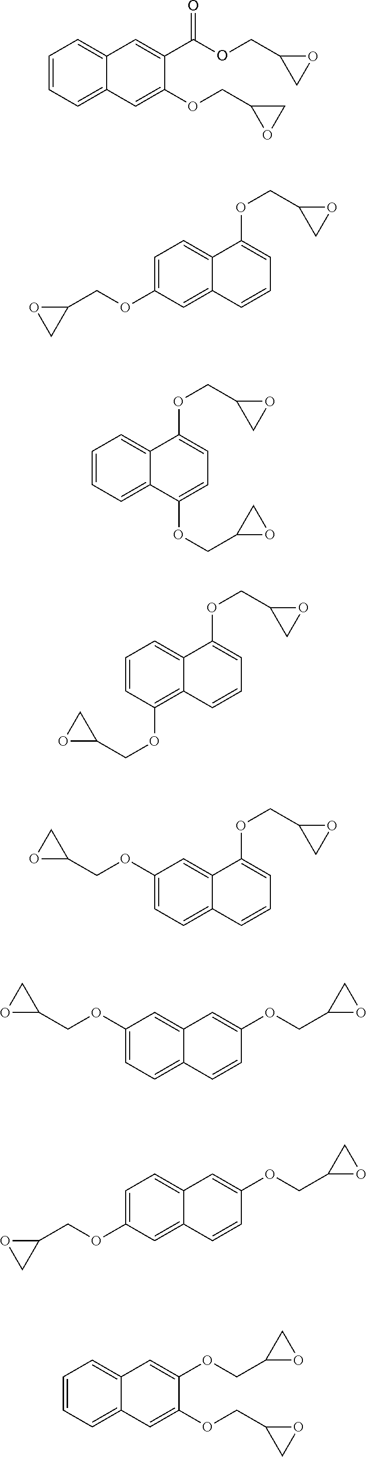

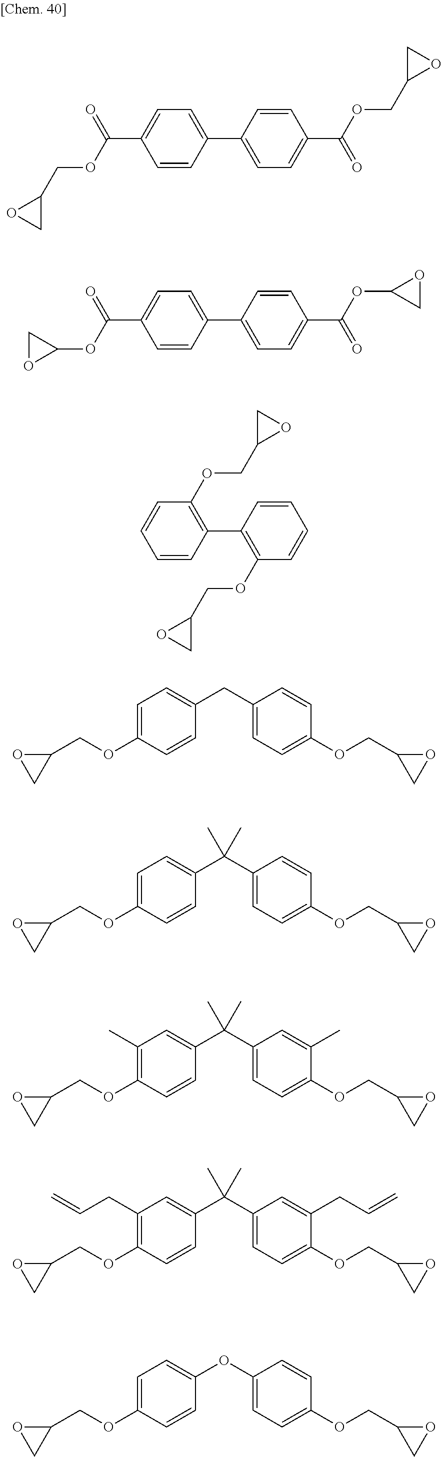

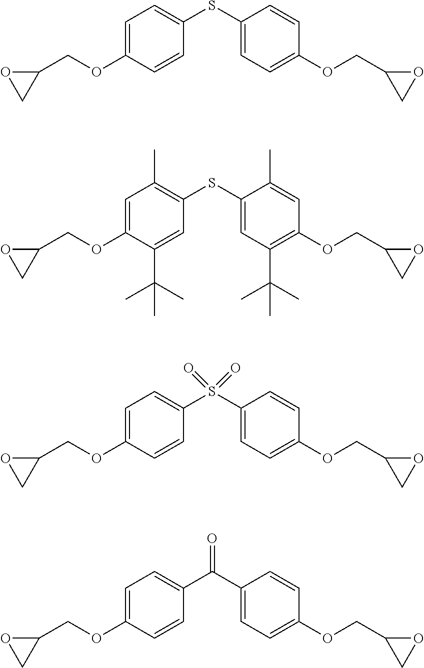 [SMILES: c1cc(Sc2ccc(OCC3CO3)cc2)ccc1OCC1CO1 ; Cc1cc(OCC2CO2)c(C(C)(C)C)cc1Sc1cc(C(C)(C)C)c(OCC2CO2)cc1C ; O=S(=O)(c1ccc(OCC2CO2)cc1)c1ccc(OCC2CO2)cc1 ; O=C(c1ccc(OCC2CO2)cc1)c1ccc(OCC2CO2)cc1]

(II) Reaction between at least one of a compound represented by the following Formula (11B) or a compound represented by the following Formula (12A) and a compound represented by the following Formula (EB):

[Chem. 41] [symbol]
where in Formula (11B), X₁ represents a group represented by any one of Formulae (1-1) to (1-3) above and the following Formula (1-4C), Z₁ and Z₂ each independently represent a single bond or a divalent group represented by Formula (1-5), provided that *3 in Formula (1-5) represents a bonding hand bonded to a nitrogen atom in Formula (11B) and
in Formula (12B), Q₁₁ represents a divalent organic group represented by any one of Formulae (2-1-1) to (2-1-4) above, and n1 and n2 each independently represent 0 or 1:

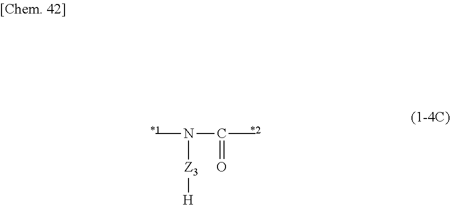

where in Formula (1-4C), Z₃ represents a single bond or a divalent group represented by Formula (1-5) above, provided that *3 in Formula (1-5) represents a bonding hand bonded to a nitrogen atom in Formula (1-4C). *1 represents a bonding hand bonded to a carbon atom in Formula (11B), and *2 represents a bonding hand bonded to a nitrogen atom in Formula (11B).

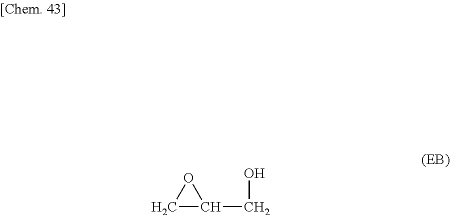

Examples of the compound represented by Formula (11B) include the following compounds.

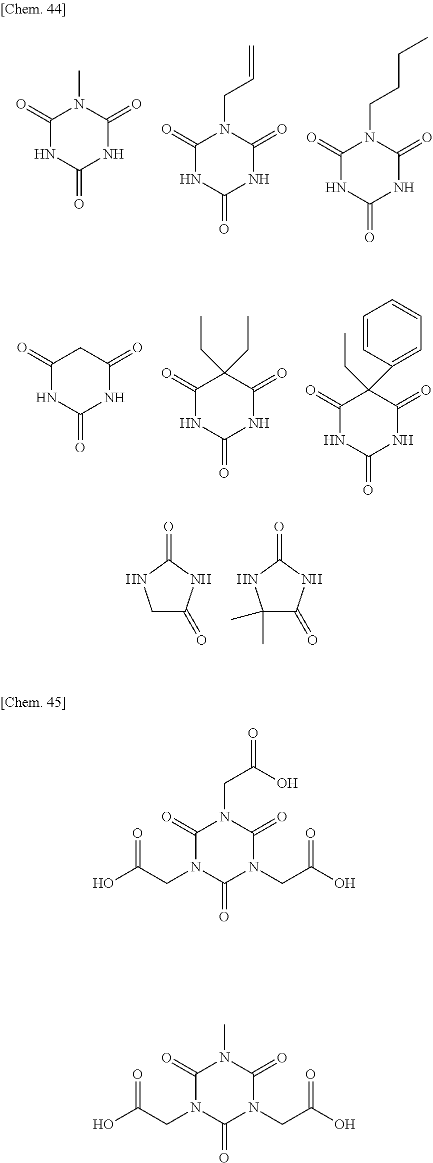

Examples of the compound represented by Formula (12B) include the following compounds.

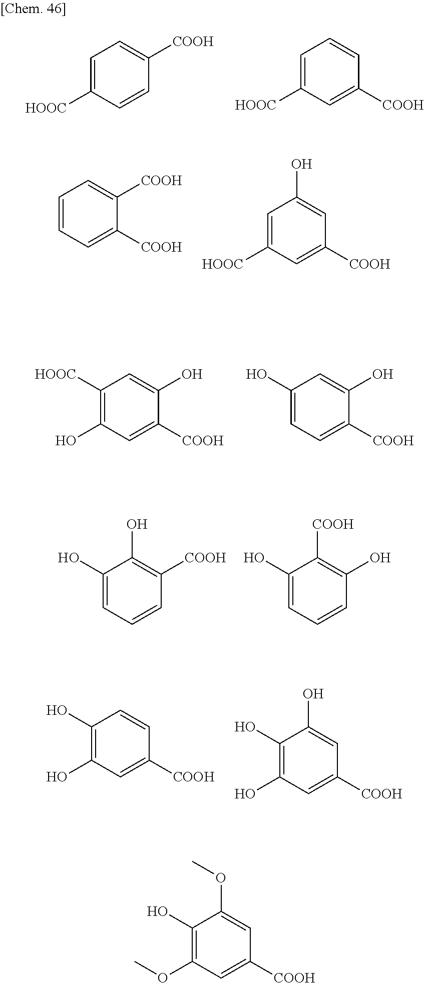

(III) Reaction between at least one of a compound represented by Formula (11A) above or a compound represented by Formula (12A) above and a compound represented by the following Formula (EC):

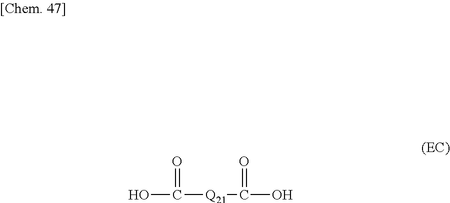

where in Formula (EC), Q₂₁ represents a single bond or a divalent organic group.

The divalent organic group may be, for example, a divalent organic group having 1 to 20 carbon atoms or a divalent organic group having 1 to 10 carbon atoms.

The divalent organic group may have a hetero atom. Examples of the heteroatom include an oxygen atom and a sulfur atom.

Examples of the divalent organic group include a hydrocarbon group having 1 to 10 carbon atoms. The hydrocarbon group may be an aliphatic hydrocarbon group or an aromatic hydrocarbon group.

Examples of the divalent organic group include a hydrocarbon group having 1 to 10 carbon atoms substituted with a hydroxy group or a mercapto group. Examples of the hydrocarbon group include an aliphatic hydrocarbon group.

Examples of the divalent organic group include a hydrocarbon group having 2 to 10 carbon atoms interrupted by an oxygen atom or a sulfur atom. Examples of the hydrocarbon group include an aliphatic hydrocarbon group.

Examples of the compound represented by Formula (EC) include the following compounds.

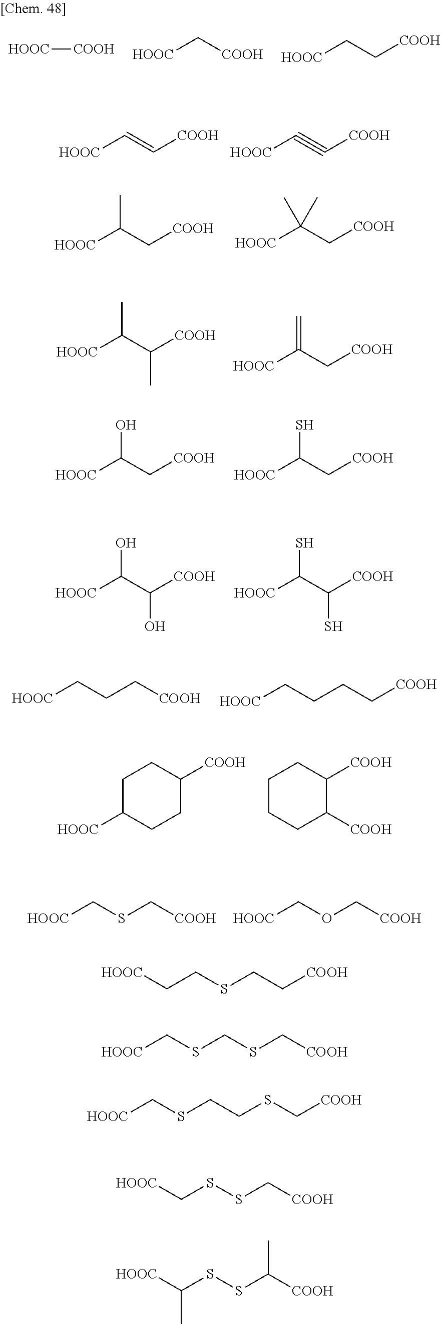

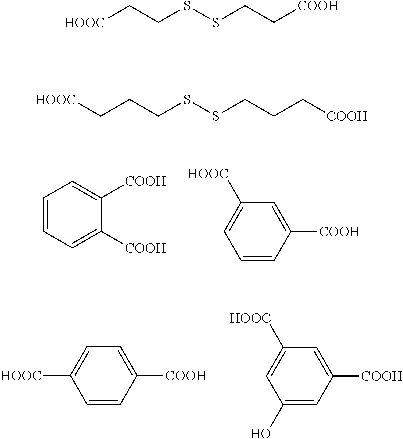 [SMILES: O=C(O)CCSSCCC(=O)O ; O=C(O)CCCSSCCCC(=O)O ; O=C(O)c1ccccc1C(=O)O ; O=C(O)c1cccc(C(=O)O)c1 ; O=C(O)c1ccc(C(=O)O)cc1 ; O=C(O)c1cc(O)cc(C(=O)O)c1]

The reactions (I) to (III) may be performed, for example, in the presence of a catalyst. The catalyst is, for example, a quaternary phosphonium salt such as tetrabutylphosphonium bromide or ethyltriphenylphosphonium bromide, or a quaternary ammonium salt such as benzyltriethylammonium chloride. The amount of the catalyst used can be appropriately selected from a range of 0.1 to 10 mass % relative to the total mass of the polymer raw material used in the reaction. The temperature and time for the polymerization reaction can be selected from, for example, the optimal conditions (temperature: 80 to 160° C. and time: 2 to 50 hours).

### <Second Component>

The second component is used for improving the application property of the resist underlayer film-forming composition.

The second component is a water-soluble polymer.

The second component is a compound different from the first component.

The water-soluble polymer is a polymer compound that dissolves in an amount of 1 g or more in 100 g of water at 25° C., preferably a polymer compound that dissolves in an amount of 5 g or more in 100 g of water at 25° C., and more preferably a polymer compound that dissolves in an amount of 10 g or more in 100 g of water at 25° C.

The water-soluble polymer is not particularly limited, and examples thereof include polyvinyl alcohol, water-soluble cellulose, polyethylene glycol (PEG), polyethylene oxide (PEO), polyvinyl pyrrolidone, polyacrylic acid, polystyrenesulfonic acid, and polyvinyl acetamide.

The polyvinyl alcohol is a polymer prepared by hydrolyzing polyvinyl acetate to change an acetyl group in the polyvinyl acetate molecule to a hydroxyl group. A value obtained by expressing the proportion of the hydroxyl group in mol % is referred to as a saponification degree. Known polyvinyl alcohols have various properties depending on their saponification degrees. For example, polyvinyl acetate (saponification degree: 0 mol %) is generally water-insoluble, and polyvinyl alcohol having a saponification degree of 100 mol % is known as water-soluble. In the case of polyvinyl alcohol having a saponification degree of 60 mol % or less among polyvinyl alcohols, the solubility in water is deteriorated. In the case of polyvinyl alcohol having a saponification degree of 30 mol % or less, the polyvinyl alcohol is not substantially dissolved. Conversely, when the saponification degree is too high, the solubility is low, and polyvinyl alcohol having a saponification degree of 85 to 90 mol % has the highest solubility. In the present invention, polyvinyl alcohol having a saponification degree of 70 mol % or more is preferably used. In general, the higher the saponification degree, the better the developer resistance. Thus, polyvinyl alcohol having a saponification degree of 75 mol % or more is preferably used. However, conversely, when the saponification degree is too high, the storage stability of the composition (generation of insoluble foreign matters) tends to be deteriorated. Thus, the saponification degree of polyvinyl alcohol is preferably 99 mol % or less, and more preferably 98 mol % or less.

The polymerization degree of polyvinyl alcohol is ordinarily represented by a viscosity of a 4 mass % aqueous solution (at 20° C.), and the viscosity is generally about 1 to 80 cps (mPa·s). Among the polyvinyl alcohols, the polyvinyl alcohol used in the present invention preferably has a viscosity of 1 cps or more, and more preferably has a viscosity of 2 cps or more. The upper limit of the viscosity is preferably 70 cps, and the upper limit of the viscosity is more preferably 65 cps, 50 cps, 40 cps, 30 cps, 20 cps, 10 cps, 8 cps, or 5 cps. The viscosity range is, for example, 1 to 20 cps, 2 to 10 cps, or 3 to 8 cps.

The polyvinyl alcohol may be modified by substituting some of its hydroxyl groups with an alkyl ether group, an alkyloxymethyl group, an acetyl acetate group, or the like.

The water-soluble cellulose is not particularly limited, and examples thereof include alkylcelluloses such as methylcellulose and ethylcellulose; hydroxyalkylcelluloses such as hydroxyethylcellulose and hydroxypropylcellulose; and hydroxyalkylalkylcelluloses such as hydroxyethylmethylcellulose and hydroxypropylmethylcellulose.

Among these water-soluble celluloses, hydroxypropylcellulose is more preferred.

As the hydroxypropylcellulose, various products having different viscosities are commercially available from various companies, and any of them can be used in the present invention. The viscosity of a 2 mass % aqueous solution of hydroxypropylcellulose (at 20° C.) is not particularly limited, and can be appropriately selected depending on the purpose. The viscosity is preferably 2.0 mPa·s (centipoise, cps) or more and 4,000 mPa·s (centipoise, cps) or less.

Further, the viscosity of hydroxypropylcellulose is considered to depend on the weight-average molecular weight, the degree of substitution, and the molecular weight of hydroxypropylcellulose.

The weight-average molecular weight of hydroxypropylcellulose is not particularly limited, and can be appropriately selected depending on the purpose. The weight-average molecular weight is preferably 15,000 or more and 400,000 or less. The weight-average molecular weight can be measured using, for example, gel permeation chromatography (GPC).

A commercially available product of hydroxypropylcellulose is not particularly limited, and can be appropriately selected depending on the purpose. Examples of the commercially available product include the following commercially available products.
HPC-SSL having a molecular weight of 15,000 or more and 30,000 or less and a viscosity of 2.0 mPa-s or more and 2.9 mPa-s or less (manufactured by Nippon Soda Co., Ltd.)
HPC-SL having a molecular weight of 30,000 or more and 50,000 or less and a viscosity of 3.0 mPa-s or more and 5.9 mPa-s or less (manufactured by Nippon Soda Co., Ltd.)
HPC-L having a molecular weight of 55,000 or more and 70,000 or less and a viscosity of 6.0 mPa-s or more and 10.0 mPa-s or less (manufactured by Nippon Soda Co., Ltd.)
HPC-M having a molecular weight of 110,000 or more and 150,000 or less and a viscosity of 150 mPa-s or more and 400 mPa-s or less (manufactured by Nippon Soda Co., Ltd.)
HPC—H having a molecular weight of 250,000 or more and 400,000 or less and a viscosity of 1,000 mPa-s or more and 4,000 mPa-s or less (manufactured by Nippon Soda Co., Ltd.)

Among these commercially available products, HPC-SSL having a molecular weight of 15,000 or more and 30,000 or less and a viscosity of 2.0 mPa-s or more and 2.9 mPa-s or less is preferred.

In the commercially available products described above, the molecular weight is measured using gel permeation chromatography (GPC), and the viscosity is measured using a 2 mass % aqueous solution (at 20° C.).

The polystyrenesulfonic acid is not particularly limited as long as it exhibits water solubility. The sulfonation rate of the polystyrenesulfonic acid may be 100%, or may be less than 100%. The sulfonation rate is, for example, 80% or more and 100% or less. Here, the “sulfonation rate” refers to a molar ratio (%) of a “styrene unit having a sulfonate group” to the total of the “styrene unit having a sulfonate group” and the “styrene unit” in the molecule of the polystyrenesulfonic acid.

That is, the polystyrenesulfonic acid may be a homopolymer formed only of a repeating unit represented by the following Formula (SS), or may be a copolymer having a repeating unit represented by the following Formula (SS) and a repeating unit represented by the following Formula (St):

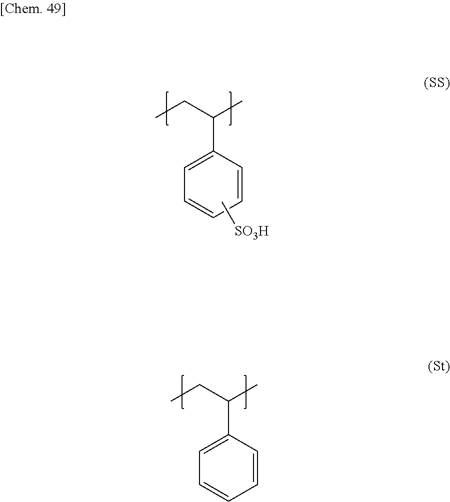

Examples of styrenesulfonic acid including polystyrenesulfonic acid include 4-styrenesulfonic acid.

The content of the second component (water-soluble polymer) in the resist underlayer film-forming composition is not particularly limited.

Addition of a small amount of the second component to the resist underlayer film-forming composition enables the application property of the resist underlayer film-forming composition to be improved.

Accordingly, a mass ratio (first component:second component) between the first component and the second component in the resist underlayer film-forming composition is preferably 99:1 to 50:50, more preferably 99:1 to 75:25, and particularly preferably 99:1 to 90:10.

### <Crosslinking Agent>

The resist underlayer film-forming composition preferably contains a crosslinking agent.

The crosslinking agent contained as an optional component in the resist underlayer film-forming composition has, for example, a functional group which reacts in itself.

Examples of the crosslinking agent include hexamethoxymethylmelamine, tetramethoxymethyl benzoguanamine, 1,3,4,6-tetrakis(methoxymethyl)glycoluril(tetramethoxymethyl glycoluril) (POWDERLINK [registered trademark]1174), 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, and 1,1,3,3-tetrakis(methoxymethyl)urea.

In addition, the crosslinking agent may be a nitrogen-containing compound having 2 to 6 substituents that bond to a nitrogen atom in one molecule as described in WO 2017/187969 A, the substituents being represented by the following Formula (1d):

### [Chem. 50]

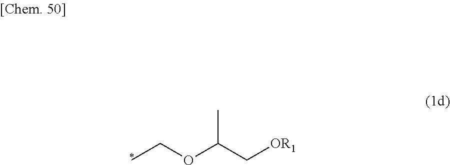

where in Formula (1d), R₁ represents a methyl group or an ethyl group, and an asterisk “*” represents a bonding hand bonded to a nitrogen atom.

The nitrogen-containing compound having 2 to 6 substituents represented by Formula (1d) above in one molecule may be a glycoluril derivative represented by the following Formula (1E):

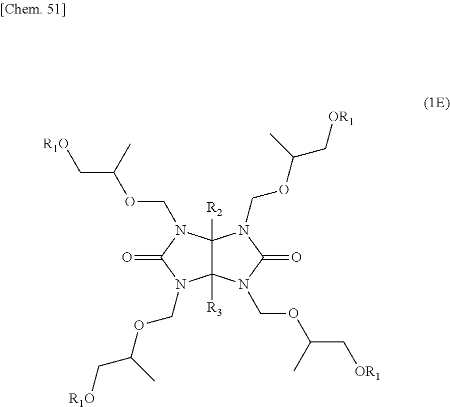

where in Formula (1E), 4 R₁s each independently represent a methyl group or an ethyl group, and R₂ and R₃ each independently represent a hydrogen atom, an alkyl group having 1 to 4 carbon atoms, or a phenyl group.

Examples of the glycoluril derivative represented by Formula (1E) above include compounds represented by the following Formulae (1E-1) to (1E-6):

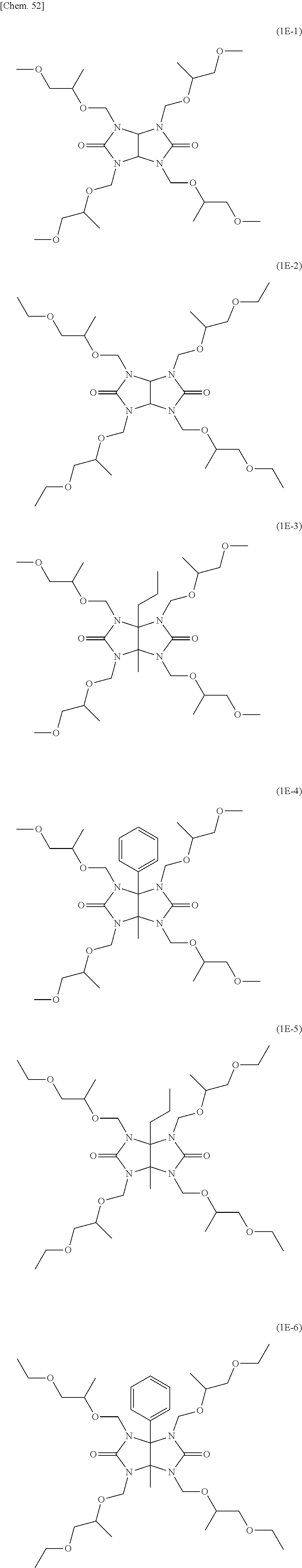

The nitrogen-containing compound having 2 to 6 substituents represented by Formula (1d) above in one molecule is prepared by reacting a nitrogen-containing compound having 2 to 6 substituents represented by the following Formula (2d) that bond to a nitrogen atom in one molecule with at least one compound represented by the following Formula (3d):

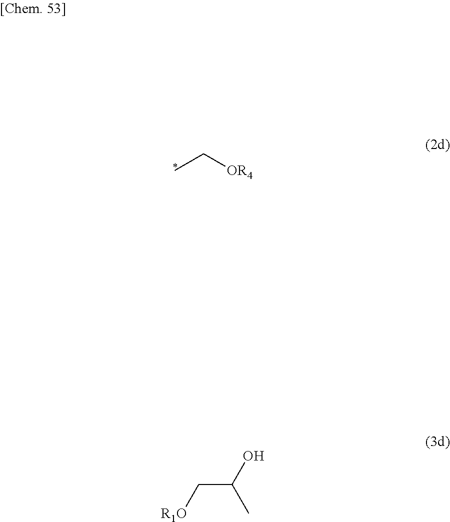

where in Formula (2d) and Formula (3d), R₁ represents a methyl group or an ethyl group, and R₄ represents an alkyl group having 1 to 4 carbon atoms, and an asterisk “*” represents a bonding hand bonded to a nitrogen atom.

The glycoluril derivative represented by Formula (1E) above is prepared by reacting a glycoluril derivative represented by the following Formula (2E) with at least one compound represented by Formula (3d) above.

The nitrogen-containing compound having 2 to 6 substituents represented by Formula (2d) above in one molecule is, for example, a glycoluril derivative represented by the following Formula (2E):

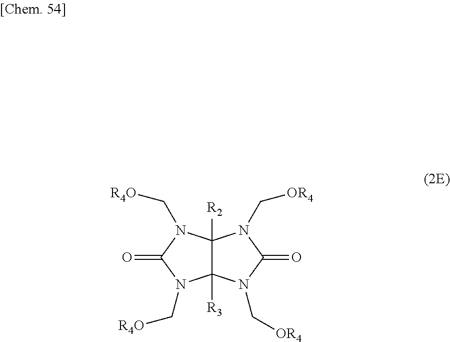

where in Formula (2E), R₂ and R₃ each independently represent a hydrogen atom, an alkyl group having 1 to 4 carbon atoms, or a phenyl group, and R₄s each independently represent an alkyl group having 1 to 4 carbon atoms.

Examples of the glycoluril derivative represented by Formula (2E) above include compounds represented by the following Formulae (2E-1) to (2E-4). Further, examples of the compound represented by Formula (3d) above include compounds represented by the following Formulae (3d-1) and (3d-2):

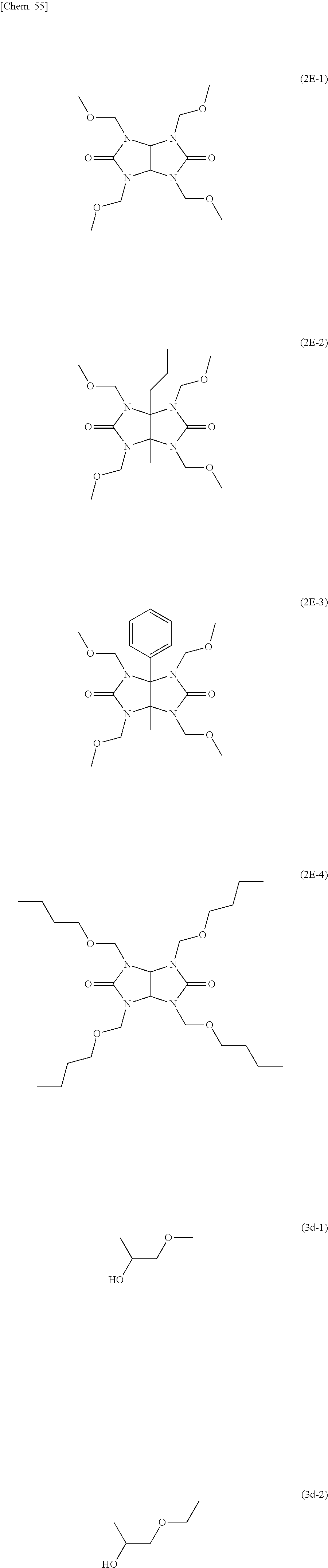

In respect of the content related to the nitrogen-containing compound having 2 to 6 substituents represented by Formula (1d) that bond to a nitrogen atom in one molecule, the entire disclosure of WO 2017/187969 A is incorporated in the present application by reference.

The crosslinking agent may be a crosslinkable compound described in WO 2014/208542 A and represented by the following Formula (G-1) or (G-2):

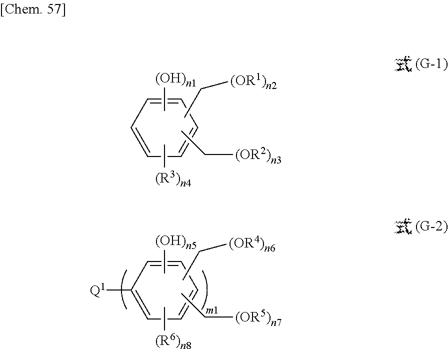

where Q¹ represents a single bond or an m1-valent organic group, R¹ and R⁴ each represent an alkyl group having 2 to 10 carbon atoms or an alkyl group having 2 to 10 carbon atoms with an alkoxy group having 1 to 10 carbon atoms, R² and R⁵ each represent a hydrogen atom or a methyl group, and R³ and R⁶ each represent an alkyl group having 1 to 10 carbon atoms or an aryl group having 6 to 40 carbon atoms,
n1 represents an integer that meets 1≤n1≤3, n2 represents an integer that meets 2≤n2≤5, n3 represents an integer that meets 0≤n3≤3, n4 represents an integer that meets 0≤n4≤3, and 3≤(n1+n2+n3+n4)≤6,
n5 represents an integer that meets 1≤n5≤3, n6 represents an integer that meets 1≤n6≤4, n7 represents an integer that meets 0≤n7≤3, n8 represents an integer that meets 0≤n8≤3, and 2≤(n5+n6+n7+n8)≤5, and
m1 represents an integer of 2 to 10.

The crosslinkable compound represented by Formula (G-1) or (G-2) above may be prepared by a reaction of a compound represented by the following Formula (G-3) or (G-4) with a hydroxyl group-containing ether compound or an alcohol having 2 to 10 carbon atoms:

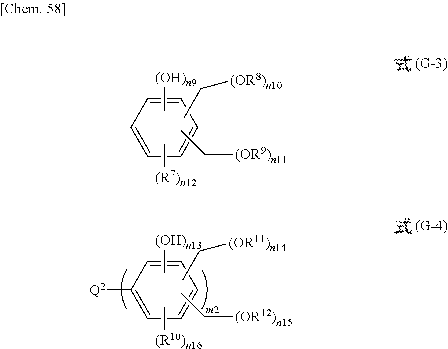

where Q² represents a single bond or an m2-valent organic group; R⁸, R⁹, R¹¹, and R¹² each represent a hydrogen atom or a methyl group, and R⁷ and R¹⁰ each represent an alkyl group having 1 to 10 carbon atoms or an aryl group having 6 to 40 carbon atoms;
n9 represents an integer that meets 1≤n9≤3, n10 represents an integer that meets 2≤n10≤5, n11 represents an integer that meets 0≤n11≤3, n12 represents an integer that meets 0≤n12≤3, and 3≤(n9+n10+n11+n12)≤6;
n13 represents an integer that meets 1≤n13≤3, n14 represents an integer that meets 1≤n14≤4, n15 represents an integer that meets 0≤n15≤3, n16 represents an integer that meets 0≤n16≤3, and 2≤(n13+n14+n15+n16)≤5; and
m2 represents an integer of 2 to 10.

The compounds represented by Formula (G-1) and Formula (G-2) above can be exemplified below.

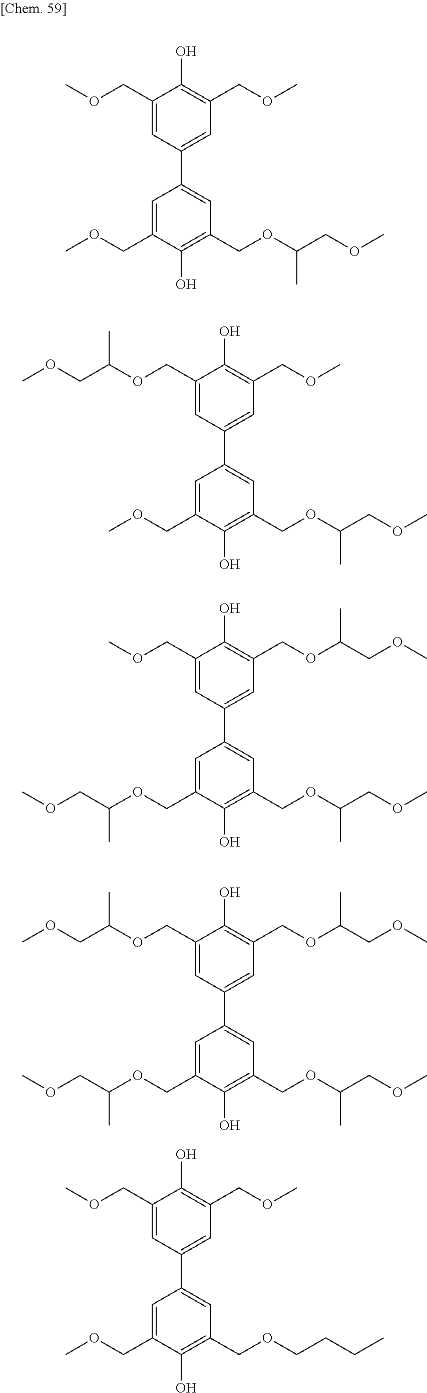

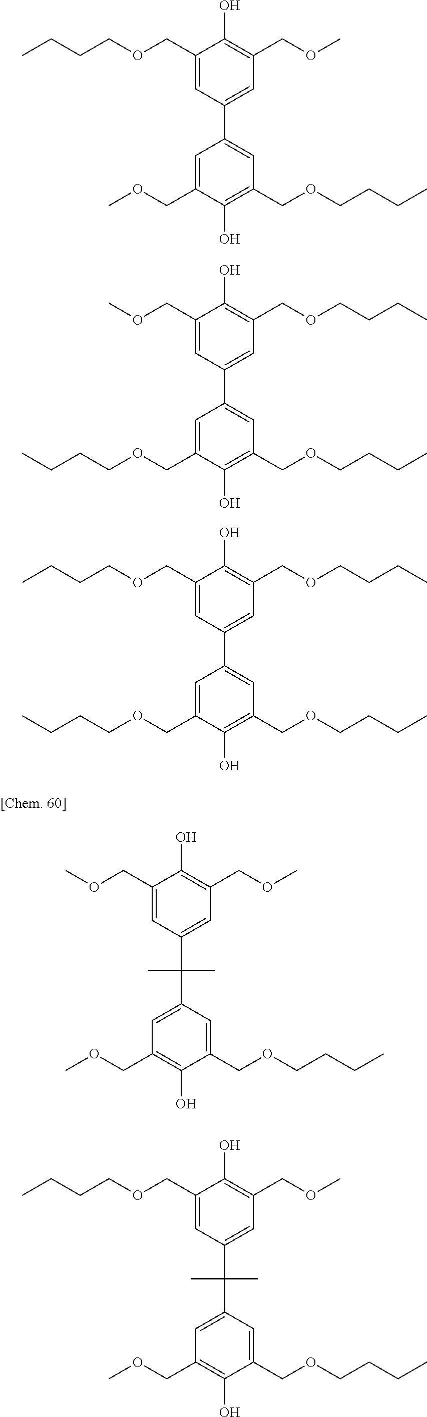

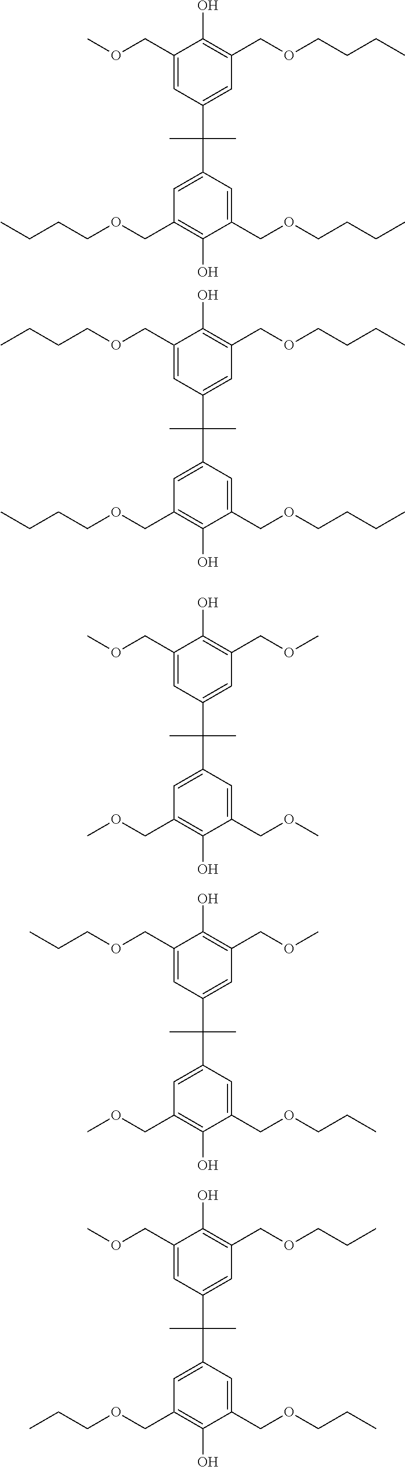

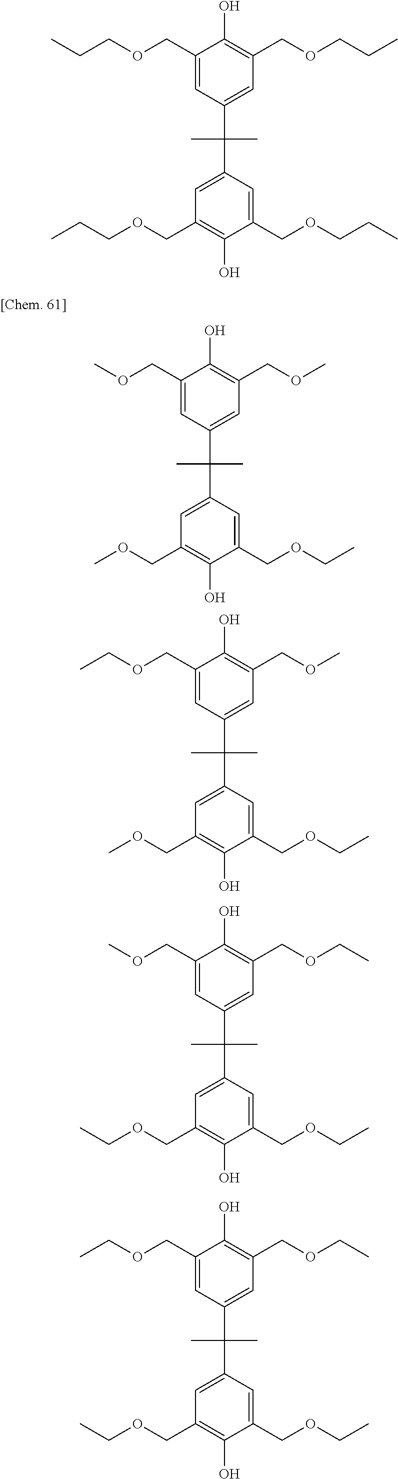

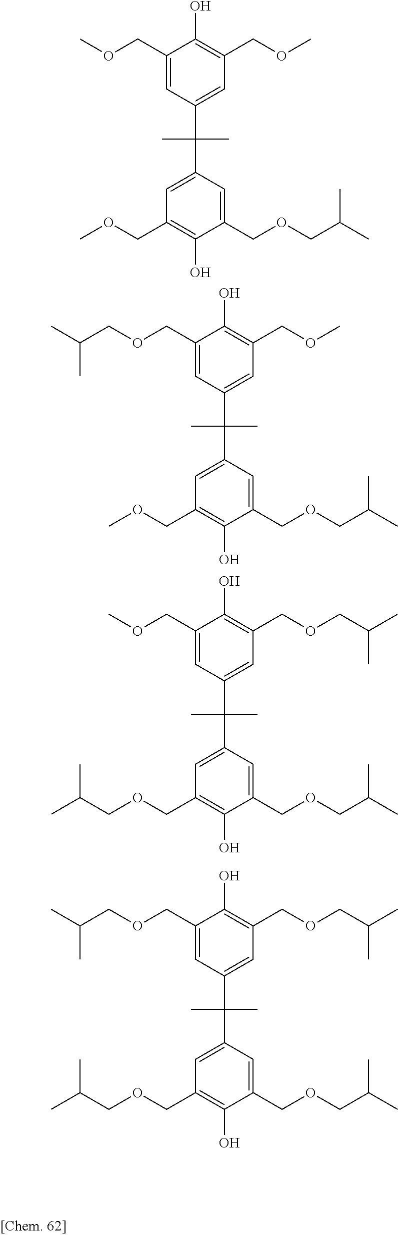

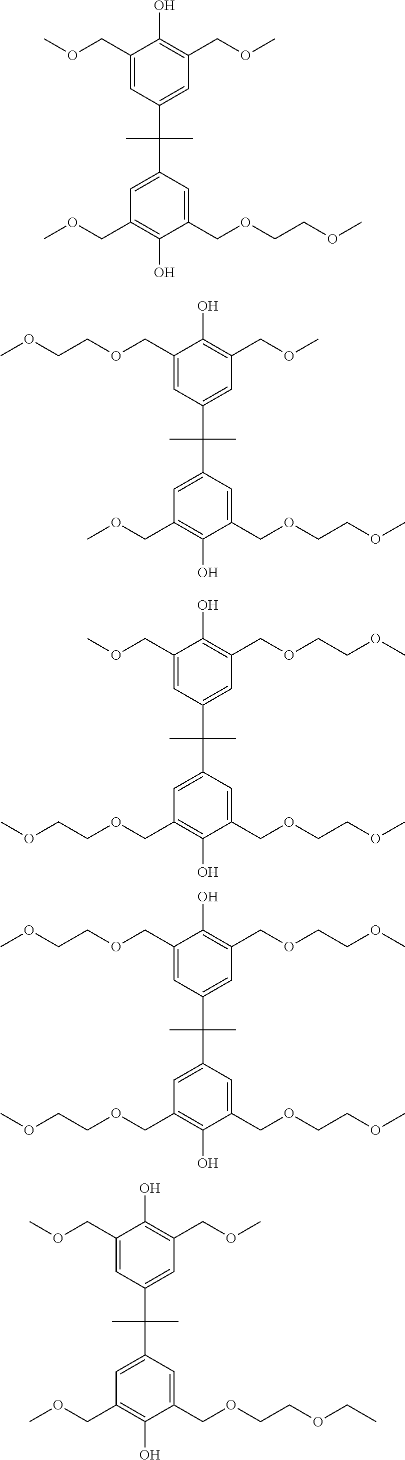

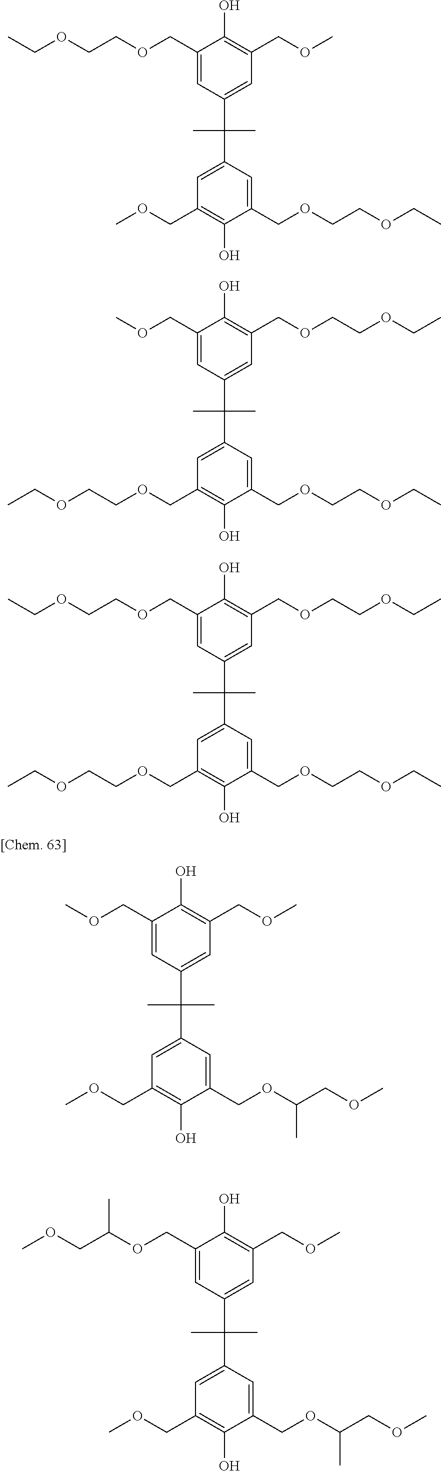

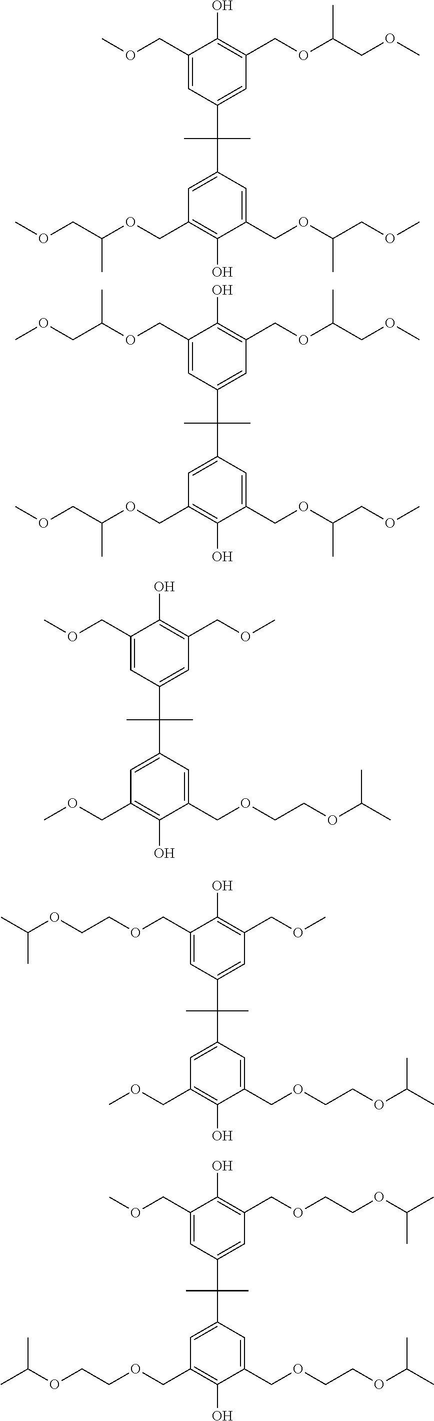

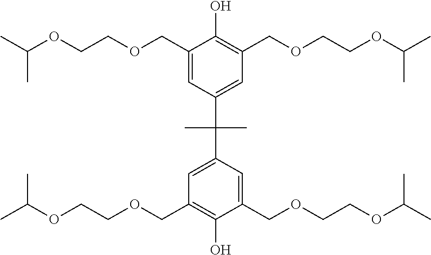 [SMILES: CC(C)OCCOCc1cc(C(C)(C)c2cc(COCCOC(C)C)c(O)c(COCCOC(C)C)c2)cc(COCCOC(C)C)c1O]

The compounds represented by Formula (G-3) and Formula (G-4) can be exemplified below.

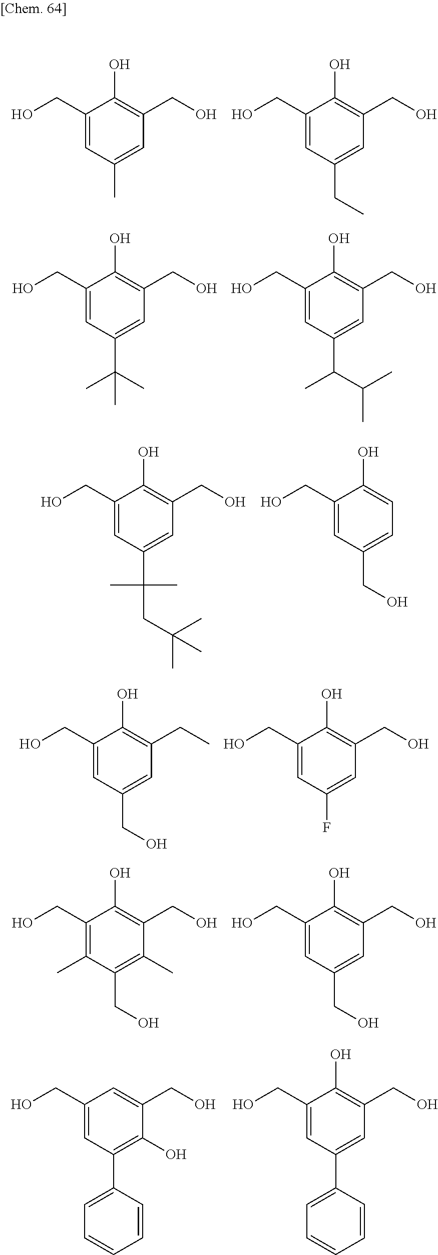

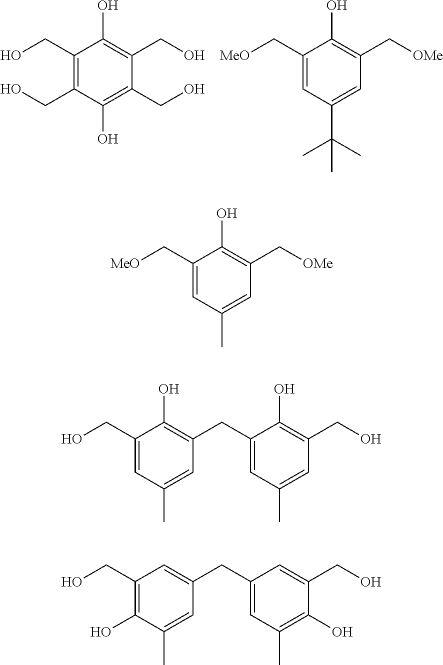

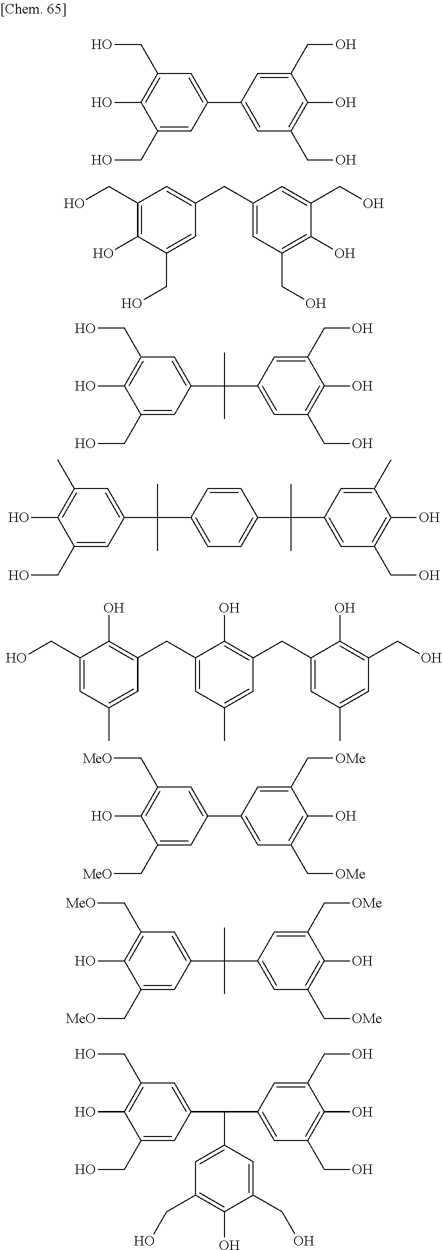

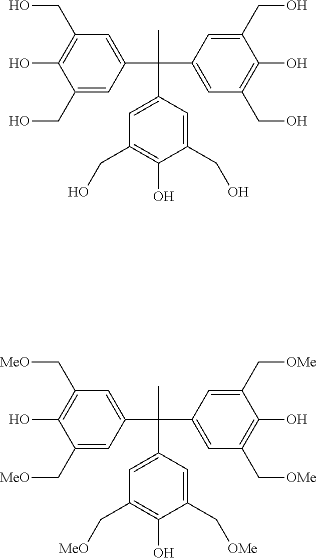

where Me represents a methyl group.

The entire disclosure of WO 2014/208542 A is incorporated in the present application by reference.

When the crosslinking agent is used, the content ratio of the crosslinking agent in the resist underlayer film-forming composition is, for example, 1 mass % to 50 mass %, preferably 5 mass % to 40 mass %, relative to the total of the first component and the second component.

When the crosslinking agent is used, the content ratio of the crosslinking agent in the resist underlayer film-forming composition is, for example, 1 mass % to 50 mass %, preferably 5 mass % to 40 mass %, relative to the total of the first component.

### <Curing Catalyst>

As the curing catalyst contained as an optional component in the resist underlayer film-forming composition, both a thermal acid generator and a photoacid generator can be used. Preferably, the thermal acid generator is used.

Examples of the thermal acid generator include sulfonic acid compounds and carboxylic acid compounds such as p-toluenesulfonic acid, trifluoromethanesulfonic acid, pyridinium-p-toluenesulfonate (pyridinium-p-toluenesulfonic acid), pyridinium phenolsulfonic acid, pyridinium-p-hydroxybenzenesulfonic acid (p-phenolsulfonic acid pyridinium salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include an onium salt compound, a sulfonimide compound, and a disulfonyldiazomethane compound.

Specific examples of the onium salt compound include, but are not limited to, iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoro normal butane sulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

The curing catalysts can be used singly or in combination two or more kinds thereof.

When a curing catalyst is used, the content ratio of the curing catalyst is, for example, 0.1 mass % to 50 mass %, preferably 1 mass % to 30 mass % relative to the crosslinking agent.

### <Solvent>

The resist underlayer film-forming composition contains a solvent.

The solvent contains water.

The solvent may contain an organic solvent in addition to water.

The solvent preferably contains water in an amount of 50 mass % or more, more preferably in an amount of 70 mass % or more, still more preferably in an amount of 80 mass % or more, and particularly preferably in an amount of 90 mass % or more, relative to the solvent.

As the organic solvent, an organic solvent generally used for a chemical for a semiconductor lithography process is preferred. Specific examples of the organic solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide, and N,N-dimethylacetamide. The solvents may be used singly or in combination of two or more kinds thereof.

Among these solvents, propylene glycol monomethyl ether, propylene glycol monomethyl ether acetate, ethyl lactate, butyl lactate, and cyclohexanone are preferred. Particularly, propylene glycol monomethyl ether and propylene glycol monomethyl ether acetate are preferred.

### <Additional Component>

In the resist underlayer film-forming composition, a surfactant can be further added in order not to generate pinholes, striation, and the like and to further improve the application property against surface irregularity.

Examples of the surfactant include nonionic surfactants such as polyoxyethylene alkyl ethers such as polyoxyethylene lauryl ether, polyoxyethylene stearyl ether, polyoxyethylene cetyl ether, and polyoxyethylene oleyl ether; polyoxyethylene alkyl allyl ethers such as polyoxyethylene octylphenol ether and polyoxyethylene nonylphenol ether; polyoxyethylene-polyoxypropylene block copolymers; sorbitan fatty acid esters such as sorbitan monolaurate, sorbitan monopalmitate, sorbitan monostearate, sorbitan monooleate, sorbitan trioleate, and sorbitan tristearate; polyoxyethylene sorbitan fatty acid esters such as polyoxyethylene sorbitan monolaurate, polyoxyethylene sorbitan monopalmitate, polyoxyethylene sorbitan monostearate,

polyoxyethylene sorbitan trioleate, and polyoxyethylene sorbitan tristearate; fluorine-based surfactants such as EFTOP EF301, EF303, and EF352 (trade name, manufactured by Tohkem Products Corporation), MEGAFAC F171, F173, and R-30 (trade name, manufactured by DIC Corporation), Fluorad FC430 and FC431 (trade name, manufactured by Sumitomo 3M Limited), and AsahiGuard AG710 and SURFLON 5-382, SC101, SC102, SC103, SC104, SC105, and SC106 (trade name, manufactured by Asahi Glass Co., Ltd.), and Organosiloxane Polymer KP341 (manufactured by Shin-Etsu Chemical Co., Ltd.).

The amount of each of these surfactants added is not particularly limited, and is ordinarily 2.0 mass % or less, and preferably 1.0 mass % or less relative to the total solid content of the resist underlayer film-forming composition.

These surfactants may be added singly, or in combination of two or more kinds thereof.

The amount of the film-forming components contained in the resist underlayer film-forming composition, i.e. the components excluding the solvent is, for example, 0.01 mass % to 10 mass % relative to the entire resist underlayer film-forming composition.

The resist underlayer film-forming composition of the present invention is produced, for example, using a method of mixing the first component, the solvent, and the like by a known method. The resist underlayer film-forming composition to be used is necessary to be in a uniform solution state. The composition after production is preferably filtered with a filter or the like, in order to remove metal impurities, foreign matters, and the like present in the composition.

One of the measures for evaluating whether the resist underlayer film-forming composition is in a uniform solution state is to observe the passing property of the composition through a specific microfilter. Preferably, the resist underlayer film-forming composition according to the present invention passes through a microfilter having a pore size of 0.1 μm, 0.05 μm, 0.03 μm, 0.02 μm, or 0.01 μm and exhibits a uniform solution state.

Examples of the material of the microfilter include fluorine-based resins such as PTFE (polytetrafluoroethylene) and PFA (tetrafluoroethylene-perfluoroalkyl vinyl ether copolymer), PE (polyethylene), UPE (ultra-high molecular weight polyethylene), PP (polypropylene), PSF (polysulfone), PES (polyether sulfone), and nylon. Among these materials, PTFE (polytetrafluoroethylene) is preferred. Since the resist underlayer film-forming composition contains water as a solvent, the filter used for filtration of the resist underlayer film-forming composition is preferably a filter subjected to a hydrophilization treatment.

### (Resist Underlayer Film)

The resist underlayer film of the present invention is a cured product of the silicon-containing resist underlayer film-forming composition described above.

The resist underlayer film can be produced, for example, by applying the resist underlayer film-forming composition described above onto a semiconductor substrate and baking the composition.

Examples of the semiconductor substrate to which the resist underlayer film-forming composition is applied include a silicon wafer, a germanium wafer, and a semiconductor wafer formed of a compound such as gallium arsenide, indium phosphide, gallium nitride, indium nitride, or aluminum nitride.

When a semiconductor substrate having an inorganic film formed on a surface thereof is used, the inorganic film is formed by, for example, an atomic layer deposition (ALD) method, a chemical vapor deposition (CVD) method, a reactive sputtering method, an ion plating method, a vacuum deposition method, or a spin coating method (spin-on glass: SOG). Examples of the inorganic film include a polysilicon film, a silicon oxide film, a silicon nitride film, a boro-phospho silicate glass (BPSG) film, a titanium nitride film, a titanium nitride oxide film, a tungsten film, a gallium nitride film, and a gallium arsenide film. The inorganic film may be a single layer or a multilayer of two or more layers. In the case of multilayers or more, the respective layers may be identical types of inorganic films or different types of inorganic films.

The thickness of the inorganic film is not particularly limited.

The resist underlayer film-forming composition of the present invention is applied onto the semiconductor substrate by an appropriate application method such as a spinner or a coater. Thereafter, the resultant semiconductor substrate is baked using a heating means such as a hot plate to form a resist underlayer film. The conditions for baking are appropriately selected from a baking temperature of 100° C. to 400° C. and a baking time of 0.3 minutes to 60 minutes. Preferably, the baking temperature is 120° C. to 350° C. and the baking time is 0.5 minutes to 30 minutes. More preferably, the baking temperature is 150° C. to 300° C. and the baking time is 0.8 minutes to 10 minutes.

The film thickness of the resist underlayer film is, for example, 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), 0.005 μm (5 nm) to 0.02 μm (20 nm), 0.005 μm (5 nm) to 0.02 μm (20 nm), 0.003 μm (3 nm) to 0.01 μm (10 nm), 0.005 μm (5 nm) to 0.1 μm (10 nm), 0.003 μm (3 nm) to 0.006 μm (6 nm), or 0.005 μm (5 nm).

The method for measuring the film thickness of the resist underlayer film in the present specification is as follows.
Name of measurement device: optical interference film thickness meter (product name: NanoSpec 6100, manufactured by Nanometrics Inc.)
Arithmetic average of four points (e.g. four points are measured at intervals of 1 cm in the X direction of the wafer.)

### (Semiconductor Processing Substrate)

The semiconductor processing substrate of the present invention includes a semiconductor substrate and the resist underlayer film of the present invention.

Examples of the semiconductor substrate include the semiconductor substrates described above.

The resist underlayer film is disposed on the semiconductor substrate, for example.

### (Method for Producing Semiconductor Element, and Method for Forming Pattern)

The method for producing a semiconductor element of the present invention includes at least the following steps:
step of forming a resist underlayer film on a semiconductor substrate using the resist underlayer film-forming composition of the present invention; and
step of forming a resist film on the resist underlayer film.

The method for forming a pattern of the present invention includes at least the following steps:
step of forming a resist underlayer film on a semiconductor substrate using the resist underlayer film-forming composition of the present invention;
step of forming a resist film on the resist underlayer film;
step of irradiating the resist film with light or an electron beam, and then developing the resist film to form a resist pattern; and
step of etching the resist underlayer film using the resist pattern as a mask.

Ordinarily, a resist film is formed on the resist underlayer film.

The film thickness of the resist film is preferably 200 nm or less, more preferably 150 nm or less, still more preferably 100 nm or less, and particularly preferably 80 nm or less. The film thickness of the resist film is preferably 10 nm or more, more preferably 20 nm or more, and particularly preferably 30 nm or more.

The resist film formed on the resist underlayer film by a known method (e.g. applying and baking) is not particularly limited as long as it responds to light or an electron beam (EB) used for irradiation. Both a negative photoresist and a positive photoresist can be used.

The light or electron beam is not particularly limited, and examples thereof include i-ray (365 nm), KrF excimer laser (248 nm), ArF excimer laser (193 nm), extreme ultraviolet (EUV; 13.5 nm), and electron beam (EB).

In the present specification, a resist responding to EB is also referred to as a photoresist.

Examples of the photoresist include a positive photoresist formed of a novolac resin and 1,2-naphthoquinone diazide sulfonic acid ester; a chemically amplified photoresist formed of a binder having a group that is decomposed by an acid to increase an alkali dissolution rate and a photoacid generator; a chemically amplified photoresist formed of a low molecular weight compound that is decomposed by an acid to increase an alkali dissolution rate of the photoresist, an alkali-soluble binder, and a photoacid generator; a chemically amplified photoresist formed of a binder having a group that is decomposed by an acid to increase an alkali dissolution rate, a low molecular weight compound having a group that is decomposed by an acid to increase an alkali dissolution rate of the photoresist, and photoacid generator; and a resist containing metal elements. Examples of the photoresist include V146G (trade name, manufactured by JSR Corporation), APEX-E (trade name, manufactured by Shipley Company L.L.C), PAR710 (trade name, manufactured by Sumitomo Chemical Co., Ltd.), and AR2772 and SEPR430 (trade name, manufactured by Shin-Etsu Chemical Co., Ltd.) Further, examples of the photoresist include a fluorine-containing atomic polymer-based photoresist as described in Proc. SPIE, Vol. 3999, 330-334 (2000), Proc. SPIE, Vol. 3999, 357-364 (2000), or Proc. SPIE, Vol. 3999, 365-374 (2000).

In addition, the resist compositions described in WO 2019/188595 A, WO 2019/187881 A, WO 2019/187803 A, WO 2019/167737 A, WO2019/167725 A, WO 2019/187445 A, WO 2019/167419 A, WO 2019/123842 A, WO 2019/054282 A, WO 2019/058945 A, WO 2019/058890 A, WO 2019/039290 A, WO 2019/044259 A, WO 2019/044231 A, WO 2019/026549 A, WO 2018/193954 A, WO 2019/172054 A, WO 2019/021975 A, WO 2018/230334 A, WO 2018/194123 A, JP 2018-180525 A, WO 2018/190088 A, JP 2018-070596 A, JP 2018-028090A, JP 2016-153409 A, JP 2016-130240 A, JP 2016-108325 A, JP 2016-047920 A, JP 2016-035570 A, JP 2016-035567 A, JP 2016-035565 A,

JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, JP 2010-128369 A, WO 2018/031896 A, JP 2019-113855 A, WO 2017/156388 A, WO 2017/066319 A, JP 2018-41099 A, WO 2016/065120 A, WO 2015/026482 A, JP 2016-29498 A, JP 2011-253185 A and the like, the so-called resist compositions such as a radiation-sensitive resin composition and a high-resolution patterning composition based on an organometallic solution, and a metal-containing resist composition may be used, but are not limited thereto.

Examples of the resist composition include the following compositions:

An active ray-sensitive or radiation-sensitive resin composition containing: a resin A having a repeating unit having an acid-decomposable group in which a polar group is protected by a protecting group that is removed by an action of an acid; and a compound represented by the following Formula (21):

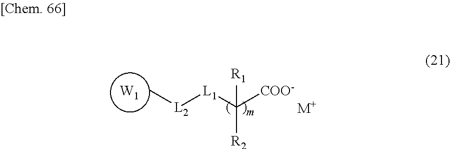

where in Formula (21), m represents an integer of 1 to 6,
R₁ and R₂ each independently represent a fluorine atom or a perfluoroalkyl group,
L₁ represents —O—, —S—, —COO—, —SO₂—, or —SO₃—,
L₂ represents an alkylene group which may have a substituent or a single bond,
W₁ represents a cyclic organic group which may have a substituent, and
M⁺ represents a cation.

A metal-containing film-forming composition for extreme ultraviolet ray or electron beam lithography, containing: a solvent and a compound having a metal-oxygen covalent bond, in which the metal elements constituting the compound belong to the third to seventh periods of Groups 3 to 15 of the periodic table.

A radiation-sensitive resin composition containing: an acid generator and a polymer having a first structural unit represented by the following Formula (31) and a second structural unit having an acid-dissociable group represented by the following Formula (32):

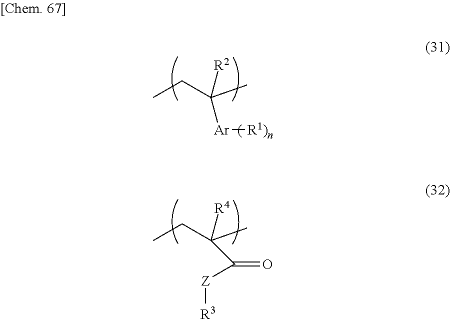

where in Formula (31), Ar is a group resulted from removal of (n+1) hydrogen atoms from arene having 6 to 20 carbon atoms; R¹ is a hydroxy group, a sulfanyl group, or a monovalent organic group having 1 to 20 carbon atoms, n is an integer of 0 to 11, when n is 2 or more, a plurality of R s is identical to or different from each other or one another, R² is a hydrogen atom, a fluorine atom, a methyl group, or a trifluoromethyl group, in Formula (32), R³ is a monovalent group having 1 to 20 carbon atoms and containing the acid-dissociable group, Z is a single bond, an oxygen atom, or a sulfur atom, and R⁴ is a hydrogen atom, a fluorine atom, a methyl group, or a trifluoromethyl group.

A resist composition containing: an acid generator and a resin (A1) having a structural unit having a cyclic carbonic acid ester structure, a structural unit represented by the following Formula, and a structural unit having an acid-unstable group:

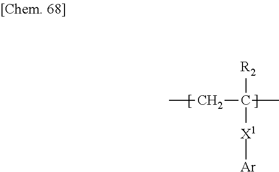

where,
R² represents an alkyl group having 1 to 6 carbon atoms which may have a halogen atom, a hydrogen atom, or a halogen atom, X¹ represents a single bond, —CO—O—*, or —CO—NR⁴—*, * represents a bonding hand with —Ar, R⁴ represents a hydrogen atom or an alkyl group having 1 to 4 carbon atoms, and Ar represents an aromatic hydrocarbon group having 6 to 20 carbon atoms which may have one or more groups selected from the group consisting of a hydroxy group and a carboxyl group.

Examples of the resist film include the following:

A resist film containing a base resin containing a repeating unit represented by the following Formula (a1) and/or a repeating unit represented by the following Formula (a2), and a repeating unit that generates an acid bonded to a polymer main chain upon exposure:

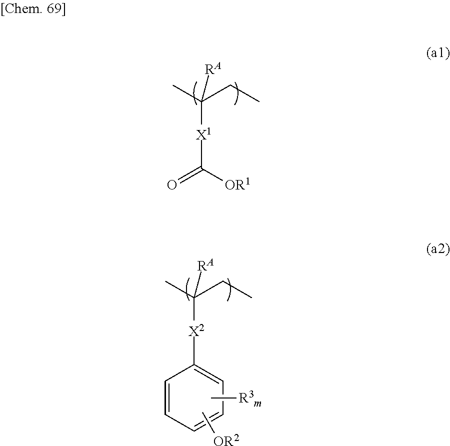

where in Formula (a1) and Formula (a2), R^{A}s each independently are a hydrogen atom or a methyl group, R¹ and R² are each independently a tertiary alkyl group having 4 to 6 carbon atoms, R s each independently are a fluorine atom or a methyl group, m is an integer of 0 to 4, X¹ is a single bond, a phenylene group or a naphthylene group, or a linking group having 1 to 12 carbon atoms containing at least one selected from an ester bond, a lactone ring, a phenylene group, and a naphthylene group, and X² is a single bond, an ester bond, or an amide bond.

Examples of the resist material include the following:

A resist material including a polymer having a repeating unit represented by the following Formula (b1) or Formula (b2):

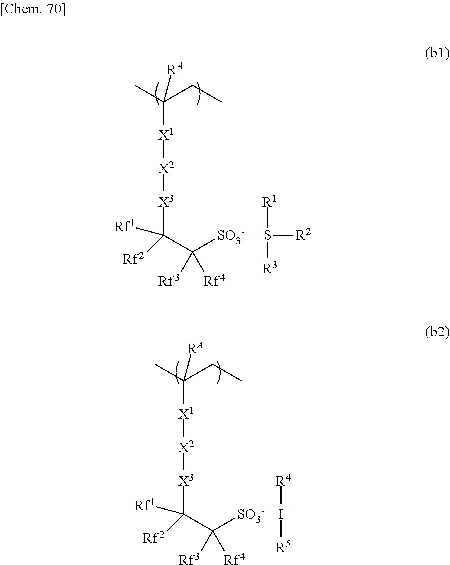

where in Formula (b1) and Formula (b2), R^{A}s each are a hydrogen atom or a methyl group; X is a single bond or an ester group; X² is a linear, branched or cyclic alkylene group having 1 to 12 carbon atoms or an arylene group having 6 to 10 carbon atoms, a part of a methylene group constituting the alkylene group may be substituted with an ether group, an ester group or a lactone ring-containing group, and at least one hydrogen atom contained in X² is substituted with a bromine atom; X³ is a single bond, an ether group, an ester group, or a linear, branched or cyclic alkylene group having 1 to 12 carbon atoms, and a part of a methylene group constituting the alkylene group may be substituted with an ether group or an ester group; Rf¹ to Rf⁴ are each independently a hydrogen atom, a fluorine atom, or a trifluoromethyl group, and at least one of Rf¹ to Rf⁴ is a fluorine atom or a trifluoromethyl group; further, Rf¹ and Rf² may be combined to form a carbonyl group; R¹ to R⁵ are each independently a linear, branched or cyclic alkyl group having 1 to 12 carbon atoms, a linear, branched or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, and some or all of the hydrogen atoms in these groups may be substituted with a hydroxy group, a carboxy group, a halogen atom, an oxo group, a cyano group, an amide group, a nitro group, a sultone group, a sulfone group, or a sulfonium salt-containing group, and a part of a methylene group constituting each of these groups may be substituted with an ether group, an ester group, a carbonyl group, a carbonate group, or a sulfonate ester group; in addition, R¹ and R² may be bonded to form a ring together with the sulfur atom to which R¹ and R² are bonded.

A resist material including a base resin including a polymer having a repeating unit represented by the following Formula (a):

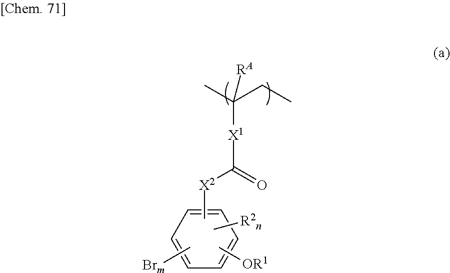

where in Formula (a), R^{A} is a hydrogen atom or a methyl group, R¹ is a hydrogen atom or an acid-unstable group, R² is a linear, branched or cyclic alkyl group having 1 to 6 carbon atoms, or a halogen atom other than bromine, X¹ is a single bond or a phenylene group, or a linear, branched or cyclic alkylene group having 1 to 12 carbon atoms which may contain an ester group or a lactone ring, X² is —O—, —O—CH₂—, or —NH—, m is an integer of 1 to 4, and u is an integer of 0 to 3, provided that m+u is an integer of 1 to 4.

A resist composition which generates an acid by exposure and whose solubility in a developer is changed by an action of an acid, the resist composition containing:
a base material component (A) whose solubility in the developer is changed by an action of an acid; and a fluorine additive component (F) which is decomposable in an alkaline developer,
in which the fluorine additive component (F) contains a fluororesin component (F1) having a structural unit (f1) containing a base-dissociable group and a structural unit (f2) containing a group represented by the following Formula (f2-r-1):

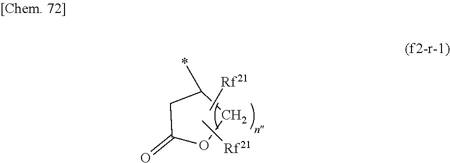

where in Formula (f2-r-1), Rf²¹s each independently represent a hydrogen atom, an alkyl group, an alkoxy group, a hydroxyl group, a hydroxyalkyl group, or a cyano group, n″ is an integer of 0 to 2, and an asterisk * is a bonding hand.

The structural unit (f1) includes a structural unit represented by the following Formula (f1-1) or a structural unit represented by the following Formula (f1-2):

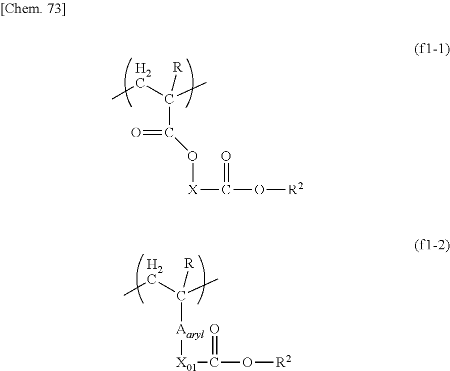

where in Formulae (f1-1) and (f1-2), Rs each independently represent a hydrogen atom, an alkyl group having 1 to 5 carbon atoms, or an alkyl halide group having 1 to 5 carbon atoms, X is a divalent linking group having no acid-dissociable site, Aaryi is a divalent aromatic cyclic group which may have a substituent, Xoi is a single bond or a divalent linking group, and R 2s are each independently an organic group having a fluorine atom.

Examples of the coating, the coating solution, and the coating composition include the following:

A coating including a metal oxo-hydroxo network having organic ligand through a metal carbon bond and/or a metal carboxylate bond.

An inorganic oxo/hydroxo-based composition.

A coating solution containing: an organic solvent; a first organometallic composition represented by Formula R_{z}SnO_{(2-(z/2)-(x/2))}(OH)ₓ (where 0<z≤2 and 0<(z+x)≤4), Formula R′ₙSnX₄₋ₙ(where n=1 or 2), or a mixture thereof, where R and R′ are independently a hydrocarbyl group having 1 to 31 carbon atoms, and X is a ligand having a hydrolyzable bond to Sn or a combination thereof; and a hydrolyzable metal compound represented by MX′ᵥ (where M is a metal selected from Groups 2 to 16 of the periodic table of the elements, v=number of 2 to 6, and X′ is a ligand having a hydrolyzable M-X bond or a combination thereof).

A coating solution containing: an organic solvent; and a first organometallic compound represented by Formula RSnO_{(3/2-x/2)} (OH)ₓ (where 0<x<3), in which about 0.0025 M to about 1.5 M tin is contained in the solution, R is an alkyl group or cycloalkyl group having 3 to 31 carbon atoms, and the alkyl group or cycloalkyl group is bonded to tin via a secondary or tertiary carbon atom.

An inorganic pattern forming precursor aqueous solution containing a mixture of water, a metal suboxide cation, a polyatomic inorganic anion, and a radiation-sensitive ligand containing a peroxide group.

Irradiation with light or an electron beam is performed, for example, through a mask (reticle) for forming a predetermined pattern.

The light exposure amount and the irradiation energy of the electron beam are not particularly limited.

Post exposure bake (PEB) may be performed after the irradiation with light or electron beam and before development.

The baking temperature is not particularly limited, and is preferably 60° C. to 150° C., more preferably 70° C. to 120° C., and particularly preferably 75° C. to 110° C.

The baking time is not particularly limited, and is preferably 1 second to 10 minutes, more preferably 10 seconds to 5 minutes, and particularly preferably 30 seconds to 3 minutes.

For the development, for example, an alkaline developer is used.

The development temperature is, for example, 5° C. to 50° C.

The developing time is, for example, 10 seconds to 300 seconds.

Examples of the alkaline developer that can be used include aqueous solutions of alkalis, e.g. inorganic alkalis such as sodium hydroxide, potassium hydroxide, sodium carbonate, sodium silicate, sodium metasilicate, and ammonia water; primary amines such as ethylamine and n-propylamine; secondary amines such as diethylamine and di-n-butyl amine; tertiary amines such as triethylamine and methyldiethylamine; alcoholamines such as dimethylethanolamine and triethanolamine; quaternary ammonium salts such as tetramethylammonium hydroxide, tetraethylammonium hydroxide, and choline; and cyclic amines such as pyrrole and piperidine. Further, it is also possible to add an appropriate amount of alcohols such as isopropyl alcohol or surfactants such as a nonionic surfactant to the aqueous solution of the alkalis. Among these, a preferred developer is an aqueous solution of quaternary ammonium salt, more preferably an aqueous solution of tetramethylammonium hydroxide and an aqueous solution of choline. Furthermore, a surfactant or the like may be added to these developers. Instead of the method using the alkaline developer, a method in which development is conducted using an organic solvent, such as butyl acetate, can be used to develop the portion of the photoresist where the alkali dissolution rate is not improved.

Next, the resist underlayer film is etched using the formed resist pattern as a mask. The etching may be dry etching or wet etching, but is preferably dry etching.

When the inorganic film is formed on the surface of the used semiconductor substrate, the surface of the inorganic film is allowed to be exposed, whereas when the inorganic film is not formed on the surface of the used semiconductor substrate, the surface of the semiconductor substrate is allowed to be exposed. Thereafter, a semiconductor device can be produced through a step of processing the semiconductor substrate by a known method (dry etching method or the like).

### EXAMPLES

Next, the contents of the present invention will be specifically described with reference to Synthesis Examples and Examples, but the present invention is not limited thereto.

The weight-average molecular weights of the polymers shown in Synthesis Examples 1 to 10 below are results measured by gel permeation chromatography (hereinafter, abbreviated as GPC). For the measurement, a GPC apparatus manufactured by Tosoh Corporation was used, and measurement conditions and the like are as follows:
Column temperature: 40° C.
Flow rate: 0.35 m1/min
Eluent: tetrahydrofuran (THF)
Standard sample: polystyrene (Tosoh Corporation)

### Synthesis Example 1

A reaction flask was charged with a mixture prepared by addition of 24.52 g of propylene glycol monomethyl ether to 16.00 g of MeDGIC (28.8 mass % propylene glycol monomethyl ether solution, manufactured by Shikoku Chemicals Corporation), 3.88 g of 1-thioglycerol (manufactured by FUJIFILM Wako Pure Chemical Corporation), and 0.45 g of tetrabutylphosphonium bromide (manufactured by Hokko Chemical Industry Co., Ltd.), and heated and stirred at 105° C. for 18 hours in a nitrogen atmosphere. The resultant reaction product was found to correspond to the following Formula (X-1), and to have a weight-average molecular weight Mw of 330 as measured by GPC in terms of polystyrene. Thereafter, the reaction product solution was added dropwise to a hexane solution, and the resultant precipitate was separated by filtration and dried at 40° C. under vacuum. The resultant compound was dissolved in ultrapure water so as to be 10 mass %.

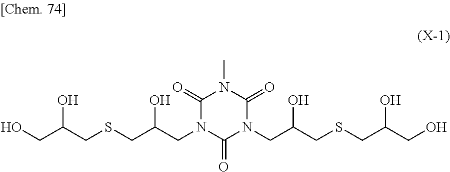 [SMILES: Cn1c(=O)n(CC(O)CSCC(O)CO)c(=O)n(CC(O)CSCC(O)CO)c1=O]

### Synthesis Example 2

A reaction flask was charged with a mixture prepared by addition of 42.68 g of propylene glycol monomethyl ether to 5.00 g of TEPIC (manufactured by Nissan Chemical Corporation), 5.45 g of 1-thioglycerol (manufactured by FUJIFILM Wako Pure Chemical Corporation), and 0.21 g of tetrabutylphosphonium bromide (manufactured by Hokko Chemical Industry Co., Ltd.), and heated and stirred at 105° C. for 23 hours in a nitrogen atmosphere. The resultant reaction product was found to correspond to the following Formula (X-2), and to have a weight-average molecular weight Mw of 470 as measured by GPC in terms of polystyrene. Thereafter, the reaction product solution was added dropwise to a hexane solution, and the resultant precipitate was separated by filtration and dried at 40° C. under vacuum. The resultant compound was dissolved in ultrapure water so as to be 10 mass %.

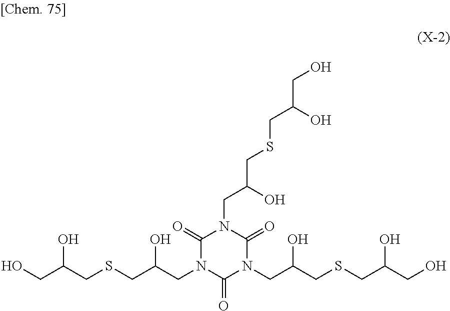 [SMILES: O=c1n(CC(O)CSCC(O)CO)c(=O)n(CC(O)CSCC(O)CO)c(=O)n1CC(O)CSCC(O)CO]

### Synthesis Example 3

A reaction flask was charged with a mixture prepared by addition of 20.32 g of propylene glycol monomethyl ether to 2.50 g of EX-201 (manufactured by Nagase ChemteX Corporation), 2.31 g of 1-thioglycerol (manufactured by FUJIFILM Wako Pure Chemical Corporation), and 0.26 g of tetrabutylphosphonium bromide (manufactured by Hokko Chemical Industry Co., Ltd.), and heated and stirred at 105° C. for 18 hours in a nitrogen atmosphere. The resultant reaction product was found to correspond to the following Formula (X-3), and to have a weight-average molecular weight Mw of 500 as measured by GPC in terms of polystyrene. Thereafter, the reaction product solution was added dropwise to a hexane solution, and the resultant precipitate was separated by filtration and dried at 40° C. under vacuum. The resultant compound was dissolved in ultrapure water so as to be 10 mass %.

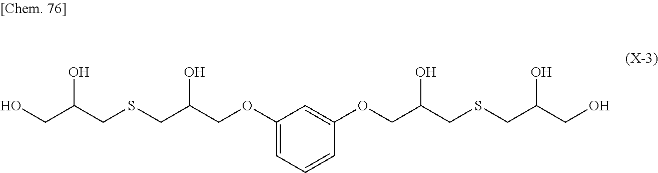 [SMILES: OCC(O)CSCC(O)COc1cccc(OCC(O)CSCC(O)CO)c1]

### Synthesis Example 4

A reaction flask was charged with a mixture prepared by addition of 37.10 g of propylene glycol monomethyl ether to 5.00 g of HP-4032D (manufactured by DIC Corporation), 3.96 g of 1-thioglycerol (manufactured by FUJIFILM Wako Pure Chemical Corporation), and 0.31 g of tetrabutylphosphonium bromide (manufactured by Hokko Chemical Industry Co., Ltd.), and heated and stirred at 105° C. for 18 hours in a nitrogen atmosphere. The resultant reaction product was found to correspond to the following Formula (X-4), and to have a weight-average molecular weight Mw of 700 as measured by GPC in terms of polystyrene. Thereafter, the reaction product solution was added dropwise to a hexane solution, and the resultant precipitate was separated by filtration and dried at 40° C. under vacuum. The resultant compound was dissolved in ultrapure water so as to be 10 mass %.

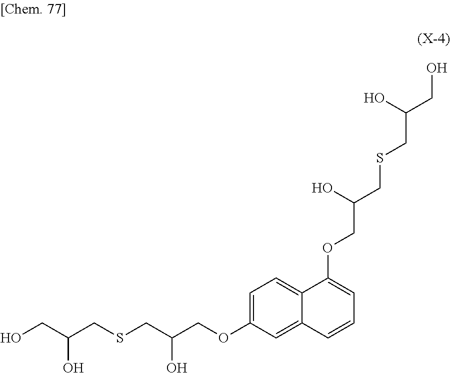 [SMILES: OCC(O)CSCC(O)COc1ccc2c(OCC(O)CSCC(O)CO)cccc2c1]

### Synthesis Example 5

A reaction flask was charged with a mixture prepared by addition of 20.36 g of propylene glycol monomethyl ether to 2.30 g of TEPIC (manufactured by Nissan Chemical Corporation), 2.74 g of succinic acid (manufactured by Tokyo Chemical Industry Co., Ltd.), and 0.04 g of tetrabutylphosphonium bromide (manufactured by Hokko Chemical Industry Co., Ltd.), and heated and stirred at 90° C. for 21 hours in a nitrogen atmosphere. The resultant reaction product was found to correspond to the following Formula (X-5), and to have a weight-average molecular weight Mw of 800 as measured by GPC in terms of polystyrene. Thereafter, the reaction product solution was added dropwise to a hexane solution, and the resultant precipitate was separated by filtration and dried at 40° C. under vacuum. The resultant compound was dissolved in ultrapure water so as to be 10 mass %.

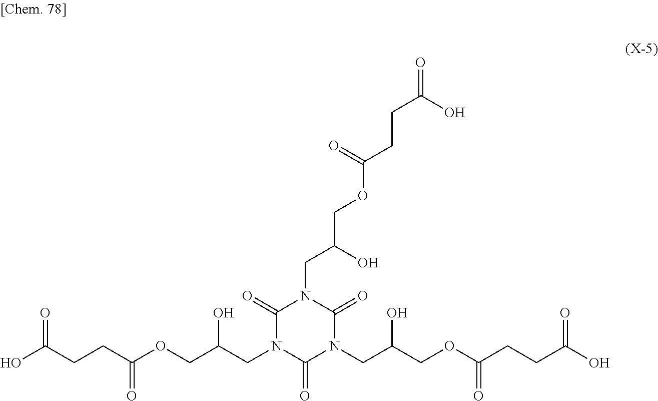 [SMILES: O=C(O)CCC(=O)OCC(O)Cn1c(=O)n(CC(O)COC(=O)CCC(=O)O)c(=O)n(CC(O)COC(=O)CCC(=O)O)c1=O]

### Synthesis Example 6

A reaction flask was charged with a mixture prepared by addition of 17.47 g of propylene glycol monomethyl ether to 2.20 g of MAICA (manufactured by Shikoku Chemicals Corporation), 2.00 g of glycidol (manufactured by FUJIFILM Wako Pure Chemical Corporation), and 0.16 g of tetrabutylphosphonium bromide (manufactured by Hokko Chemical Industry Co., Ltd.), and heated and stirred at 105° C. for 22 hours in a nitrogen atmosphere. The resultant reaction product was found to correspond to the following Formula (X-6), and to have a weight-average molecular weight Mw of 400 as measured by GPC in terms of polystyrene. Thereafter, the reaction product solution was added dropwise to a hexane solution, and the resultant precipitate was separated by filtration and dried at 40° C. under vacuum. The resultant compound was dissolved in ultrapure water so as to be 10 mass %.

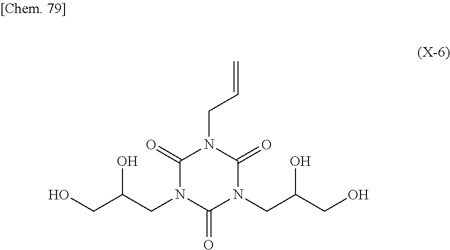 [SMILES: C=CCn1c(=O)n(CC(O)CO)c(=O)n(CC(O)CO)c1=O]

### Synthesis Example 7

A reaction flask was charged with a mixture prepared by addition of 21.73 g of propylene glycol monomethyl ether to 3.37 g of monomethyl dicarboxy methyl isocyanuric acid, 2.00 g of glycidol (manufactured by FUJIFILM Wako Pure Chemical Corporation), and 0.55 g of tetrabutylphosphonium bromide (manufactured by Hokko Chemical Industry Co., Ltd.), and heated and stirred at 105° C. for 22 hours in a nitrogen atmosphere. The resultant reaction product was found to correspond to the following Formula (X-7), and to have a weight-average molecular weight Mw of 460 as measured by GPC in terms of polystyrene. Thereafter, the reaction product solution was added dropwise to a hexane solution, and the resultant precipitate was separated by filtration and dried at 40° C. under vacuum. The resultant compound was dissolved in ultrapure water so as to be 10 mass %.

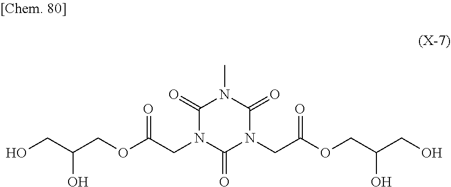 [SMILES: Cn1c(=O)n(CC(=O)OCC(O)CO)c(=O)n(CC(=O)OCC(O)CO)c1=O]

### Synthesis Example 8

A reaction flask was charged with a mixture prepared by addition of 21.56 g of propylene glycol monomethyl ether to 2.90 g of tricarboxymethyl isocyanurate, 2.40 g of glycidol (manufactured by FUJIFILM Wako Pure Chemical Corporation), and 0.08 g of tetrabutylphosphonium bromide (manufactured by Hokko Chemical Industry Co., Ltd.), and heated and stirred at 105° C. for 21 hours in a nitrogen atmosphere. The resultant reaction product was found to correspond to the following Formula (X-8), and to have a weight-average molecular weight Mw of 550 as measured by GPC in terms of polystyrene. Thereafter, the reaction product solution was added dropwise to a hexane solution, and the resultant precipitate was separated by filtration and dried at 40° C. under vacuum. The resultant compound was dissolved in ultrapure water so as to be 10 mass %.

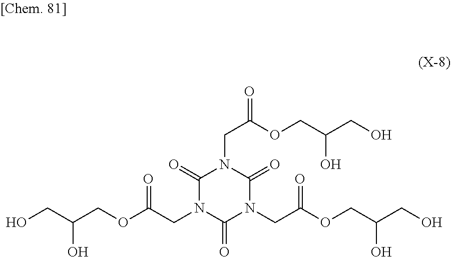 [SMILES: O=C(Cn1c(=O)n(CC(=O)OCC(O)CO)c(=O)n(CC(=O)OCC(O)CO)c1=O)OCC(O)CO]

### Synthesis Example 9

A reaction flask was charged with a mixture prepared by addition of 17.54 g of propylene glycol monomethyl ether to 2.16 g of isophthalic acid (manufactured by Tokyo Chemical Industry Co., Ltd.), 2.00 g of glycidol (manufactured by FUJIFILM Wako Pure Chemical Corporation), and 0.22 g of tetrabutylphosphonium bromide (manufactured by Hokko Chemical Industry Co., Ltd.), and heated and stirred at 105° C. for 22 hours in a nitrogen atmosphere. The resultant reaction product was found to correspond to the following Formula (X-9), and to have a weight-average molecular weight Mw of 450 as measured by GPC in terms of polystyrene. Thereafter, the reaction product solution was added dropwise to a hexane solution, and the resultant precipitate was separated by filtration and dried at 40° C. under vacuum. The resultant compound was dissolved in ultrapure water so as to be 10 mass %.

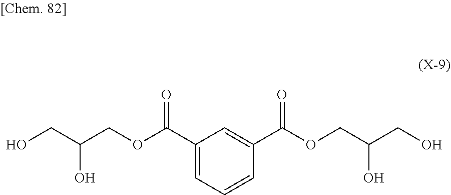 [SMILES: O=C(OCC(O)CO)c1cccc(C(=O)OCC(O)CO)c1]

### Synthesis Example 10

A reaction flask was charged with a mixture prepared by addition of 25.7 g of ultrapure water to 3.00 g of TEPIC (manufactured by Nissan Chemical Corporation), 3.29 g of 1-thioglycerol (manufactured by FUJIFILM Wako Pure Chemical Corporation), and 0.13 g of tetrabutylphosphonium bromide (manufactured by Hokko Chemical Industry Co., Ltd.), and heated and stirred at 100° C. for 14 hours in a nitrogen atmosphere. The resultant reaction product was found to correspond to the following Formula (X-2), and to have a weight-average molecular weight Mw of 530 as measured by GPC in terms of polystyrene.

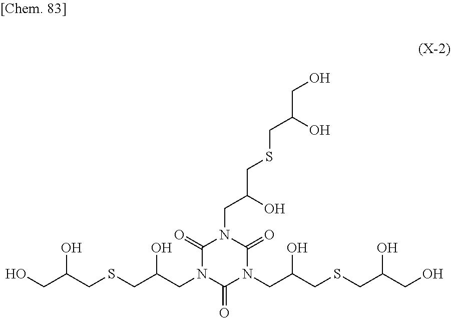 [SMILES: O=c1n(CC(O)CSCC(O)CO)c(=O)n(CC(O)CSCC(O)CO)c(=O)n1CC(O)CSCC(O)CO]

### Example 1

To 7.33 g of the aqueous solution (solid content: 10 mass %) of the reaction product prepared in Synthesis Example 1, 0.18 g of tetramethoxymethyl glycoluril, 0.02 g of pyridinium p-toluenesulfonic acid (manufactured by Tokyo Chemical Industry Co., Ltd.), 0.03 g of hydroxypropylcellulose (HPC-SSL, Nippon Soda Co., Ltd.), and 92.41 g of ultrapure water were added to prepare a solution. The solution was filtered using a hydrophilic PTFE syringe filter having a pore size of 0.02 μm to prepare a resist underlayer film-forming composition.

### Example 2

To 7.33 g of the aqueous solution (solid content: 10 mass %) of the reaction product prepared in Synthesis Example 2, 0.18 g of tetramethoxymethyl glycoluril, 0.02 g of pyridinium p-toluenesulfonic acid (manufactured by Tokyo Chemical Industry Co., Ltd.), 0.03 g of hydroxypropylcellulose (HPC-SSL, Nippon Soda Co., Ltd.), and 92.41 g of ultrapure water were added to prepare a solution. The solution was filtered using a hydrophilic PTFE syringe filter having a pore size of 0.02 μm to prepare a resist underlayer film-forming composition.

### Example 3

To 7.33 g of the aqueous solution (solid content: 10 mass %) of the reaction product prepared in Synthesis Example 3, 0.18 g of tetramethoxymethyl glycoluril, 0.02 g of pyridinium p-toluenesulfonic acid (manufactured by Tokyo Chemical Industry Co., Ltd.), 0.03 g of hydroxypropylcellulose (HPC-SSL, Nippon Soda Co., Ltd.), and 92.41 g of ultrapure water were added to prepare a solution. The solution was filtered using a hydrophilic PTFE syringe filter having a pore size of 0.02 μm to prepare a resist underlayer film-forming composition.

### Example 4

To 7.33 g of the aqueous solution (solid content: 10 mass %) of the reaction product prepared in Synthesis Example 4, 0.18 g of tetramethoxymethyl glycoluril, 0.02 g of pyridinium p-toluenesulfonic acid (manufactured by Tokyo Chemical Industry Co., Ltd.), 0.03 g of hydroxypropylcellulose (HPC-SSL, Nippon Soda Co., Ltd.), and 92.41 g of ultrapure water were added to prepare a solution. The solution was filtered using a hydrophilic PTFE syringe filter having a pore size of 0.02 μm to prepare a resist underlayer film-forming composition.

### Example 5

To 7.33 g of the aqueous solution (solid content: 10 mass %) of the reaction product prepared in Synthesis Example 5, 0.18 g of tetramethoxymethyl glycoluril, 0.02 g of pyridinium p-toluenesulfonic acid (manufactured by Tokyo Chemical Industry Co., Ltd.), 0.03 g of hydroxypropylcellulose (HPC-SSL, Nippon Soda Co., Ltd.), and 92.41 g of ultrapure water were added to prepare a solution. The solution was filtered using a hydrophilic PTFE syringe filter having a pore size of 0.02 μm to prepare a resist underlayer film-forming composition.

### Example 6

To 7.33 g of the aqueous solution (solid content: 10 mass %) of the reaction product prepared in Synthesis Example 6, 0.18 g of tetramethoxymethyl glycoluril, 0.02 g of pyridinium p-toluenesulfonic acid (manufactured by Tokyo Chemical Industry Co., Ltd.), 0.03 g of hydroxypropylcellulose (HPC-SSL, Nippon Soda Co., Ltd.), and 92.41 g of ultrapure water were added to prepare a solution. The solution was filtered using a hydrophilic PTFE syringe filter having a pore size of 0.02 μm to prepare a resist underlayer film-forming composition.

### Example 7

To 7.33 g of the aqueous solution (solid content: 10 mass %) of the reaction product prepared in Synthesis Example 7, 0.18 g of tetramethoxymethyl glycoluril, 0.02 g of pyridinium p-toluenesulfonic acid (manufactured by Tokyo Chemical Industry Co., Ltd.), 0.03 g of hydroxypropylcellulose (HPC-SSL, Nippon Soda Co., Ltd.), and 92.41 g of ultrapure water were added to prepare a solution. The solution was filtered using a hydrophilic PTFE syringe filter having a pore size of 0.02 μm to prepare a resist underlayer film-forming composition.

### Example 8

To 7.33 g of the aqueous solution (solid content: 10 mass %) of the reaction product prepared in Synthesis Example 8, 0.18 g of tetramethoxymethyl glycoluril, 0.02 g of pyridinium p-toluenesulfonic acid (manufactured by Tokyo Chemical Industry Co., Ltd.), 0.03 g of hydroxypropylcellulose (HPC-SSL, Nippon Soda Co., Ltd.), and 92.41 g of ultrapure water were added to prepare a solution. The solution was filtered using a hydrophilic PTFE syringe filter having a pore size of 0.02 μm to prepare a resist underlayer film-forming composition.

### Example 9

To 7.33 g of the aqueous solution (solid content: 10 mass %) of the reaction product prepared in Synthesis Example 9, 0.18 g of tetramethoxymethyl glycoluril, 0.02 g of pyridinium p-toluenesulfonic acid (manufactured by Tokyo Chemical Industry Co., Ltd.), 0.03 g of hydroxypropylcellulose (HPC-SSL, Nippon Soda Co., Ltd.), and 92.41 g of ultrapure water were added to prepare a solution. The solution was filtered using a hydrophilic PTFE syringe filter having a pore size of 0.02 μm to prepare a resist underlayer film-forming composition.

### Example 10

To 7.33 g of the aqueous solution of the reaction product prepared in Synthesis Example 2 (solid content: 10 mass %), 0.18 g of tetramethoxymethyl glycoluril, 0.02 g of pyridinium p-toluenesulfonic acid (manufactured by Tokyo Chemical Industry Co., Ltd.), 0.03 g of polyvinyl alcohol (PXP-05, JAPAN VAM & POVAL CO., LTD.), and 92.41 g of ultrapure water were added to prepare a solution. The solution was filtered using a hydrophilic PTFE syringe filter having a pore size of 0.02 μm to prepare a resist underlayer film-forming composition.

### Example 11

To 9.19 g of the aqueous solution (solid content: 10 mass %) of the reaction product prepared in Synthesis Example 2, 0.03 g of pyridinium trifluoromethanesulfonic acid (manufactured by Tokyo Chemical Industry Co., Ltd.), 0.05 g of hydroxypropylcellulose (HPC-SSL, Nippon Soda Co., Ltd.), and 90.72 g of ultrapure water were added to prepare a solution. The solution was filtered using a hydrophilic PTFE syringe filter having a pore size of 0.02 μm to prepare a resist underlayer film-forming composition.

### Example 12

To 13.59 g of the aqueous solution (solid content: 10 mass %) of the reaction product prepared in Synthesis Example 2, 0.04 g of polystyrenesulfonic acid (manufactured by Sigma-Aldrich Co. LLC.) and 86.36 g of ultrapure water were added to prepare a solution. The solution was filtered using a hydrophilic PTFE syringe filter having a pore size of 0.02 μm to prepare a resist underlayer film-forming composition.

### [Resist Solvent Resistance Test]

Each of the resist underlayer film-forming compositions prepared in Examples 1 to 12 was applied (spin-coated) onto a silicon wafer with a spin coater. The composition-applied silicon wafer after was heated on a hot plate at 205° C. for 1 minute to form an applied film (underlayer film) having a film thickness of 25 nm. Next, in order to confirm the solvent resistance of the underlayer film, the silicon wafer after formation of the underlayer film was immersed in a mixed solvent prepared by mixing propylene glycol monomethyl ether and propylene glycol monomethyl ether acetate at a mass ratio of 7:3 for 1 minute, spin-dried, and then baked at 100° C. for 30 seconds. The film thickness of the protective film before and after immersion in the mixed solvent was measured with an optical interference film thickness meter (product name: NanoSpec 6100, manufactured by Nanometrics Inc.).

The solvent resistance was evaluated by calculating the film thickness reduction rate (%) of the underlayer film removed by immersion in the solvent according to the following calculation formula:

$$Film thickness reduction rate ( \% ) = ( ( A - B ) \div A ) \times 100$$

A: Film thickness before immersion in solvent
B: Film thickness after immersion in solvent

The results are shown in Table 1. When the film thickness reduction rate is about 1% or less, it can be said that the film has sufficient solvent resistance.

TABLE 1

| | Film thickness |
|---|---|
| Examples | reduction rate |
| Example 1 | −0.2% |
| Example 2 | 0.0% |
| Example 3 | −0.2% |
| Example 4 | 0.0% |
| Example 5 | 0.0% |
| Example 6 | −0.1% |
| Example 7 | 0.0% |
| Example 8 | 0.0% |
| Example 9 | −0.2% |
| Example 10 | 0.0% |
| Example 11 | −0.1% |
| Example 12 | 0.0% |

From the above results, the films formed from the resist underlayer film-forming compositions of Examples 1 to 12 had a very small change in film thickness even after being immersed in the solvent. Accordingly, the films formed from the resist underlayer film-forming compositions of Examples 1 to 12 have sufficient solvent resistance to function as an underlayer film.

In Examples 1, 3, 6, 9, and 11, the film thickness reduction rate is negative, but there is no particular problem.

### [Evaluation of Optical Parameters]

Each of the resist underlayer film-forming compositions prepared in Examples 2, 10, 11, and 12 was applied onto a silicon wafer with a spin coater. The composition-applied silicon wafer was heated on a hot plate at 205° C. for 1 minute to form a resist underlayer film (film thickness: 30 nm). Then, for these resist underlayer films, an n value (refractive index) and a k value (attenuation coefficient or extinction coefficient) at a wavelength of 193 nm were measured using a spectroscopic ellipsometer (product name: VUV-VASE VU-302, manufactured by J. A. Woollam). The measurement results of the optical parameters are shown in Table 2.

TABLE 2

| Examples | n/k @193 nm |
|---|---|
| Example 2 | 1.91/0.22 |
| Example 10 | 1.89/0.22 |
| Example 11 | 1.89/0.23 |
| Example 12 | 1.87/0.25 |

### [Formation of Resist Pattern]

An example in which a resist underlayer film is formed and a resist pattern is formed thereon will be described below. The resist underlayer film-forming composition prepared in Example 2 was applied onto a substrate in which a 50-nm-thick SiON film (nitrogen-containing silicon oxide film) had been formed on a silicon wafer with a spin coater. Then, the resultant substrate was baked on a hot plate (at 205° C. for 1 min) to form a resist underlayer film having a film thickness of 20 nm to 30 nm. A commercially available photoresist solution (trade name: AR2772, manufactured by JSR Corporation) was applied onto the resist underlayer film with a spin coater, and baked on a hot plate (e.g. at 110° C. for 90 seconds) to form a photoresist film having a film thickness of 100 nm.

Next, the photoresist film was exposed to light using a scanner [NSRS307E, manufactured by Nikon Corporation; wavelength: 193 nm, NA: 0.85, o: 0.85/0.93 (Dipole)] through a photomask set such that a line width of the photoresist and the width between lines of the photoresist both become 0.065 μm, i.e. 0.065 μm L/S (dense line), and nine of such lines were to be formed, after development. Thereafter, the photoresist film was subjected to post exposure bake (PEB) on a hot plate at 110° C. for 90 seconds, and cooled. Then, the photoresist film was developed in a 60-second single paddle-type process in accordance with industrial standards using a 0.26 N tetramethylammonium hydroxide aqueous solution as a developer. A resist pattern was formed through the above process.

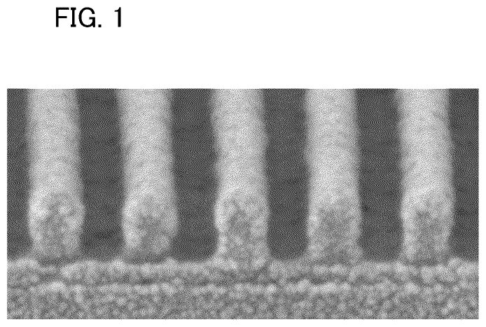

A cross section of the resultant photoresist pattern in a direction perpendicular to the substrate, i.e. the silicon wafer was observed with a scanning electron microscope (SEM). As the observation result, the cross section of the photoresist pattern was favorable straight skirt-shaped, i.e. approximately rectangular. FIG. 1 shows an SEM image resulted from photographing the cross section of the photoresist pattern finally formed on the substrate using the resist underlayer film-forming composition of Example 2.

1. A resist underlayer film-forming composition comprising:
a first component;
a second component; and
a solvent,
wherein the second component is a water-soluble polymer,
a mass ratio (first component:second component) between the first component and the second component is 99:1 to 50:50, and
the solvent contains water in an amount of 50 mass % or more relative to the solvent.

2. A resist underlayer film-forming composition comprising:
a first component; and
a solvent,
wherein the first component is a compound containing at least one selected from a structure represented by the following Formula (1) and a structure represented by the following Formula (2), and
the solvent contains water in an amount of 50 mass % or more relative to the solvent: 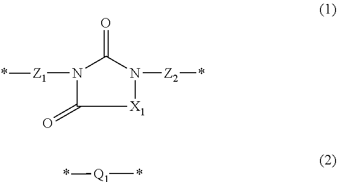
where in Formula (1), X₁ represents a group represented by any one of the following Formulae (1-1) to (1-4), and Z₁ and Z₂ each independently represent a single bond or a divalent group represented by the following Formula (1-5),
in Formula (2), Q₁ represents a divalent organic group having at least one selected from an aromatic hydrocarbon ring and an aliphatic hydrocarbon ring: 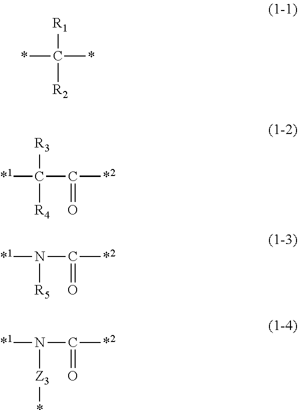
where in Formulae (1-1) to (1-3), R₁ to R₅ each independently represent a hydrogen atom, an alkyl group having 1 to 10 carbon atoms and optionally interrupted by an oxygen atom or a sulfur atom, an alkenyl group having 2 to 10 carbon atoms and optionally interrupted by an oxygen atom or a sulfur atom, an alkynyl group having 2 to 10 carbon atoms and optionally interrupted by an oxygen atom or a sulfur atom, a benzyl group or a phenyl group, and the phenyl group is optionally substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R₁ and R₂ may be bonded together to form a ring having 3 to 6 carbon atoms, and R₃ and R₄ may be bonded together to form a ring having 3 to 6 carbon atoms,
in Formula (1-4), Z₃ represents a single bond or a divalent group represented by the following Formula (1-5),
each asterisk * represents a bonding hand,*1 represents a bonding hand bonded to a carbon atom in Formula (1), and *2 represents a bonding hand bonded to a nitrogen atom in Formula (1): 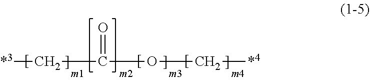
where in Formula (1-5), m1 is an integer of 0 to 4, m2 is 0 or 1, m3 is 0 or 1, and m4 is an integer of 0 to 2, provided that when m3 is 1, m1 and m2 do not simultaneously become 0, *3 represents a bonding hand bonded to a nitrogen atom in Formula (1) or (1-4), and *4 represents a bonding hand.

3. The resist underlayer film-forming composition according to claim 1, wherein the first component is a compound containing at least one selected from a structure represented by the following Formula (1) and a structure represented by the following Formula (2): 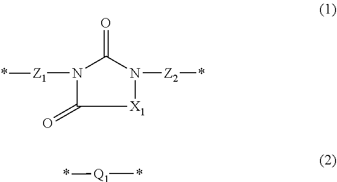
where in Formula (1), X₁ represents a group represented by any one of the following Formulae (1-1) to (1-4), and Z₁ and Z₂ each independently represent a single bond or a divalent group represented by the following Formula (1-5),
in Formula (2), Q₁ represents a divalent organic group having at least one selected from an aromatic hydrocarbon ring and an aliphatic hydrocarbon ring: 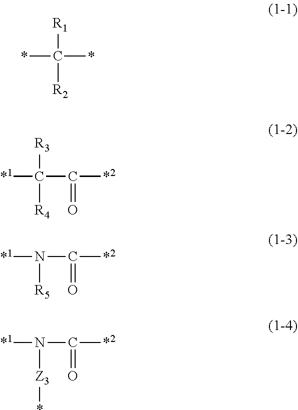
where in Formulae (1-1) to (1-3), R₁ to R₅ each independently represent a hydrogen atom, an alkyl group having 1 to 10 carbon atoms and optionally interrupted by an oxygen atom or a sulfur atom, an alkenyl group having 2 to 10 carbon atoms and optionally interrupted by an oxygen atom or a sulfur atom, an alkynyl group having 2 to 10 carbon atoms and optionally interrupted by an oxygen atom or a sulfur atom, a benzyl group or a phenyl group, and the phenyl group is optionally substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R₁ and R₂ may be bonded together to form a ring having 3 to 6 carbon atoms, and R₃ and R₄ may be bonded together to form a ring having 3 to 6 carbon atoms,
in Formula (1-4), Z₃ represents a single bond or a divalent group represented by the following Formula (1-5), and
each asterisk * represents a bonding hand, *1 represents a bonding hand bonded to a carbon atom in Formula (1), and *2 represents a bonding hand bonded to a nitrogen atom in Formula (1): 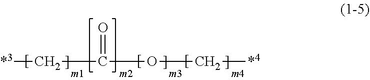
where in Formula (1-5), m1 is an integer of 0 to 4, m2 is 0 or 1, m3 is 0 or 1, and m4 is an integer of 0 to 2, provided that when m3 is 1, m1 and m2 do not simultaneously become 0, *3 represents a bonding hand bonded to a nitrogen atom in Formula (1) or (1-4), and *4 represents a bonding hand.

4. The resist underlayer film-forming composition according to claim 2, wherein Q₁ is represented by the following Formula (2-1): 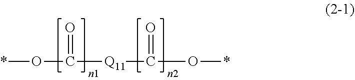
where in Formula (2-1), Q₁₁ represents a divalent organic group represented by any one of the following Formulae (2-1-1) to (2-1-4), n1 and n2 each independently represent 0 or 1, and each asterisk * represents a bonding hand: 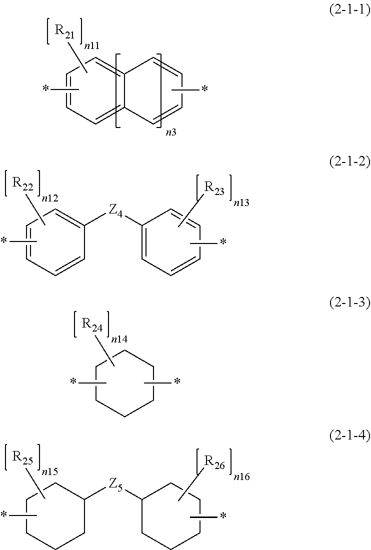
where in Formulae (2-1-1) to (2-1-4), R₂₁ to R₂₆ each independently represent a halogen atom, a hydroxy group, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms, and each asterisk * represents a bonding hand,
in Formula (2-1-1), n3 represents 0 or 1, when n3 is 0, n11 represents an integer of 0 to 4, when n3 is 1, n11 represents an integer of 0 to 6, and when R₂₁ is two or more, the two or more R₂₁s may be identical to or different from each other or one another,
in Formula (2-1-2), Z₄ represents a single bond, an oxygen atom, a sulfur atom, a carbonyl group, a sulfonyl group, or an alkylene group having 1 to 6 carbon atoms, n12 and n13 each independently represent an integer of 0 to 4, when R₂₂ is two or more, the two or more R₂₂s may be identical to or different from each other or one another, and when R₂₃ is two or more, the two or more R₂₃s may be identical to or different from each other or one another,
in Formula (2-1-3), n14 represents an integer of 0 to 4, and when R₂₄ is two or more, the two or more R₂₄s may be identical to or different from each other or one another, and
in Formula (2-1-4), Z₅ represents a single bond, an oxygen atom, a sulfur atom, a carbonyl group, a sulfonyl group, or an alkylene group having 1 to 6 carbon atoms, n15 and n16 each independently represent an integer of 0 to 4, when R₂₅ is two or more, the two or more R₂₅s may be identical to or different from each other or one another, and when R₂₆ is two or more, the two or more R₂₆s may be identical to or different from each other or one another.

5. The resist underlayer film-forming composition according to claim 2, wherein the first component includes at least one of a structure represented by the following Formula (E-1) or a structure represented by the following Formula (E-2): 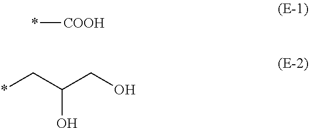
where in Formulae (E-1) and (E-2), each asterisk * represents a bonding hand.

6. The resist underlayer film-forming composition according to claim 2, further comprising a second component, wherein the second component is a water-soluble polymer.

7. The resist underlayer film-forming composition according to claim 6, wherein the water-soluble polymer is at least one selected from polyvinyl alcohol, polystyrenesulfonic acid, and water-soluble cellulose.

8. The resist underlayer film-forming composition according to claim 6, wherein a mass ratio (first component:second component) between the first component and the second component is 99:1 to 50:50.

9. The resist underlayer film-forming composition according to claim 1, further comprising a crosslinking agent.

10. The resist underlayer film-forming composition according to claim 1, further comprising a curing catalyst.

11. A resist underlayer film which is a cured product of the resist underlayer film-forming composition according to claim 1.

12. A semiconductor processing substrate comprising:
a semiconductor substrate; and
the resist underlayer film according to claim 11.

13. A method for producing a semiconductor element, the method comprising the steps of:
forming a resist underlayer film on a semiconductor substrate using the resist underlayer film-forming composition according to claim 1; and
forming a resist film on the resist underlayer film.

14. A method for forming a pattern comprising the steps of:
forming a resist underlayer film on a semiconductor substrate using the resist underlayer film-forming composition according to claim 1;
forming a resist film on the resist underlayer film;
irradiating the resist film with light or an electron beam, and then developing the resist film to form a resist pattern; and
etching the resist underlayer film using the resist pattern as a mask.

15. The resist underlayer film-forming composition according to claim 3, wherein Q₁ is represented by the following Formula (2-1): 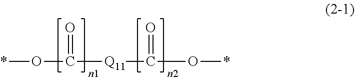
where in Formula (2-1), Q₁₁ represents a divalent organic group represented by any one of the following Formulae (2-1-1) to (2-1-4), n1 and n2 each independently represent 0 or 1, and each asterisk * represents a bonding hand: 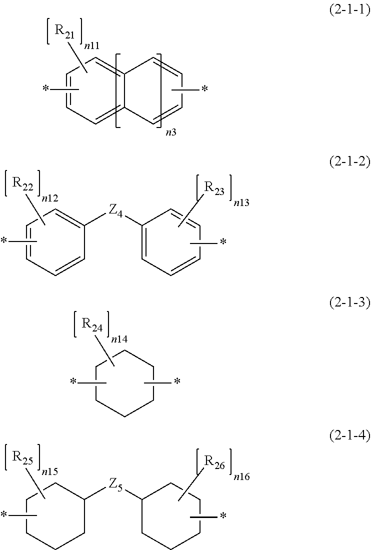
where in Formulae (2-1-1) to (2-1-4), R₂₁ to R₂₆ each independently represent a halogen atom, a hydroxy group, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms, and each asterisk * represents a bonding hand,
in Formula (2-1-1), n3 represents 0 or 1, when n3 is 0, n11 represents an integer of 0 to 4, when n3 is 1, n11 represents an integer of 0 to 6, and when R₂₁ is two or more, the two or more R₂₁s may be identical to or different from each other or one another,
in Formula (2-1-2), Z₄ represents a single bond, an oxygen atom, a sulfur atom, a carbonyl group, a sulfonyl group, or an alkylene group having 1 to 6 carbon atoms, n12 and n13 each independently represent an integer of 0 to 4, when R₂₂ is two or more, the two or more R₂₂s may be identical to or different from each other or one another, and when R₂₃ is two or more, the two or more R₂₃s may be identical to or different from each other or one another,
in Formula (2-1-3), n14 represents an integer of 0 to 4, and when R₂₄ is two or more, the two or more R₂₄s may be identical to or different from each other or one another, and
in Formula (2-1-4), Z₅ represents a single bond, an oxygen atom, a sulfur atom, a carbonyl group, a sulfonyl group, or an alkylene group having 1 to 6 carbon atoms, n15 and n16 each independently represent an integer of 0 to 4, when R₂₅ is two or more, the two or more R₂₅s may be identical to or different from each other or one another, and when R₂₆ is two or more, the two or more R₂₆s may be identical to or different from each other or one another.

16. The resist underlayer film-forming composition according to claim 1, wherein the water-soluble polymer is at least one selected from polyvinyl alcohol, polystyrenesulfonic acid, and water-soluble cellulose.

17. A resist underlayer film which is a cured product of the resist underlayer film-forming composition according to claim 2.

18. A semiconductor processing substrate comprising:
a semiconductor substrate; and
the resist underlayer film according to claim 17.

19. A method for producing a semiconductor element, the method comprising the steps of:
forming a resist underlayer film on a semiconductor substrate using the resist underlayer film-forming composition according to claim 2; and
forming a resist film on the resist underlayer film.

20. A method for forming a pattern comprising the steps of:
forming a resist underlayer film on a semiconductor substrate using the resist underlayer film-forming composition according to claim 2;
forming a resist film on the resist underlayer film;
irradiating the resist film with light or an electron beam, and then developing the resist film to form a resist pattern; and
etching the resist underlayer film using the resist pattern as a mask.
